(19) United States
(12) Patent Application Publication
(10) Pub. No.: US 2026/0362959 A1
(43) Pub. Date: Nov. 12, 2026

(54) METHOD FOR FABRICATING ORGANIC SEMICONDUCTOR DEVICE, METHOD FOR FABRICATING LIGHT-EMITTING DEVICE, AND METHOD FOR FABRICATING PHOTOSENSOR

(71) Applicant: SEMICONDUCTOR ENERGY LABORATORY CO., LTD., Atsugi-shi, Kanagawa-ken (JP)

(72) Inventors: Yasuhiro NIIKURA, Komae, Tokyo (JP); Sachiko KAWAKAMI, Atsugi, Kanagawa (JP); Naoaki HASHIMOTO, Sagamihara, Kanagawa (JP); Koichi TAKESHIMA, Sano, Tochigi (JP); Masaru OHTSUKA, Ota, Gumma (JP); Yasutaka NAKAZAWA, Tochigi, Tochigi (JP)

(21) Appl. No.: 19/481,922

(22) PCT Filed: May 13, 2024
(86) PCT No.: PCT/IB2024/054615

§ 371 Date: Nov. 6, 2025

(30) Foreign Application Priority Data
May 19, 2023 (JP) 2023-083302

(51) Int. Cl. H10K 71/16

(52) U.S. Cl. CPC H10K 71/166

(57) ABSTRACT

A method for fabricating an organic semiconductor device that can be used for a high-resolution organic semiconductor apparatus and can inhibit generation of defects is provided. The method for fabricating the organic semiconductor device includes a step of forming a first layer over a first electrode; a step of forming, over the first layer, a second layer including a material forming a structure body having a projecting shape; a step of forming a third layer over the first layer and the structure body; a step of processing the third layer into a predetermined shape; and a step of processing the first layer using the processed third layer as a mask. The first layer is an organic semiconductor layer, and the third layer includes a material different from an organic semiconductor and a material included in the second layer.

### TECHNICAL FIELD

One embodiment of the present invention relates to an organic compound, an organic EL device, a display module, a lighting module, a display apparatus, a light-emitting apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor apparatus, a display apparatus, a liquid crystal display apparatus, a light-emitting apparatus, a lighting device, a power storage device, a memory device, an imaging device, a driving method thereof, and a manufacturing method thereof.

### BACKGROUND ART

Organic EL devices including organic compounds and utilizing electroluminescence (EL) (organic EL devices) have been put to more practical use. In the basic structure of such organic EL devices, an organic compound layer containing a light-emitting material (an EL layer) is held between a pair of electrodes. Carriers are injected by application of voltage to the device, and recombination energy of the carriers is used, whereby light emission can be obtained from the light-emitting material.

Such organic EL devices are of self-luminous type and thus have advantages over liquid crystal devices, such as high visibility and no need for a backlight when used for pixels of a display, and are particularly suitable for flat panel displays. Displays including such organic EL devices are also highly advantageous in that they can be thin and lightweight. Another feature is an extremely fast response speed.

Since light-emitting layers of such organic EL devices can be formed two-dimensionally and continuously, planar light emission can be obtained. This feature is difficult to realize with point light sources typified by incandescent lamps and LEDs or linear light sources typified by fluorescent lamps; thus, the organic EL devices also have great potential as planar light sources, which can be used for lighting and the like.

Light-emitting apparatuses including organic EL devices are suitable for a variety of electronic appliances as described above, and research and development of organic EL devices has progressed for better characteristics.

In order to obtain a higher-resolution light-emitting apparatus using an organic EL device, patterning an organic layer by a photolithography method using a photoresist or the like, instead of an evaporation method using a metal mask, has been studied. By using the photolithography method, a high-resolution light-emitting apparatus in which the distance between EL layers is several micrometers can be obtained (see Patent Document 1, for example).

### REFERENCE

### Patent Document

[Patent Document 1] Japanese Translation of PCT International Application No. 2018-521459

### SUMMARY OF THE INVENTION

### Problems to be Solved by the Invention

In performing shape processing of an organic semiconductor layer by a photolithography method, a layer to be a layer that protects the organic semiconductor layer (hereinafter also referred to as a protective layer) is formed over the organic layer in some cases.

The protective layer needs to satisfy many conditions such as causing small damage to an organic layer in forming and performing shape processing of the protective layer and having low selectivity with respect to etching in performing shape processing of the organic layer. However, even when the protective layer satisfies these conditions, the protective layer might be separated or removed in a step that is not a step of separating the protective layer (processing of the protective layer or processing of the organic layer). One of the presumable factors is low adhesion between the protective layer and the organic layer. When the protective layer is separated or removed during a step in which the organic layer needs to be protected, expected processing cannot be performed and the target organic semiconductor layer cannot be formed, which causes defects.

In view of the above, an object of one embodiment of the present invention is to provide a method for fabricating an organic semiconductor device capable of inhibiting generation of defects. Another object of one embodiment of the present invention is to provide a method for fabricating an organic semiconductor device applicable to a high-resolution organic semiconductor apparatus and capable of inhibiting generation of defects. Another object of one embodiment of the present invention is to provide a method for fabricating an organic semiconductor device capable of fabricating an organic semiconductor device with favorable characteristics. Another object of one embodiment of the present invention is to provide a method for fabricating an organic semiconductor device with favorable yield.

### Means for Solving the Problems

That is, one embodiment of the present invention is a method for fabricating an organic semiconductor device including a step of forming a first layer over a first electrode; a step of forming, over the first layer, a second layer including a material forming a structure body having a projecting shape; a step of forming a third layer over the first layer and the second layer; a step of processing the third layer into a predetermined shape; a step of processing the first layer using the processed third layer as a mask; the first layer is an organic semiconductor layer; and the third layer includes a material different from materials included in the first layer and the second layer.

Alternatively, another embodiment of the present invention is a method for fabricating an organic semiconductor device including a step of forming a first layer over a first electrode; a step of forming, over the first layer, a second layer including a material forming a structure body having a projecting shape; a step of forming a third layer over the first layer and the second layer; a step of forming a fourth layer over the third layer; a step of processing the third layer and the fourth layer into predetermined shapes; a step of processing the first layer using one or both of the processed third layer and the processed fourth layer as masks; the first layer is an organic semiconductor layer; the third layer and the fourth layer include materials different from materials included in the first layer and the second layer; and the third layer and the fourth layer include different materials.

Alternatively, another embodiment of the present invention is the method for fabricating an organic semiconductor device with the above structure, in which the first layer is processed by dry etching or wet etching.

Alternatively, another embodiment of the present invention is the method for fabricating an organic semiconductor device with the above structure, in which the fourth layer is a layer including an inorganic compound.

Alternatively, another embodiment of the present invention is the method for fabricating an organic semiconductor device with the above structure, in which the fourth layer is one or more selected from aluminum, indium, tungsten, molybdenum, gallium, zinc, silicon, and an oxide or a nitride thereof.

Alternatively, another embodiment of the present invention is the method for fabricating an organic semiconductor device with the above structure, in which the material included in the second layer has a glass transition temperature lower than or equal to 120 °C.

Alternatively, another embodiment of the present invention is the method for fabricating an organic semiconductor device with the above structure, in which a crystallization temperature is observed in one or both of a temperature rising step and a temperature decreasing step in differential scanning calorimetry of the material included in the second layer.

Alternatively, another embodiment of the present invention is the method for fabricating an organic semiconductor device with the above structure, in which a width of the structure body is greater than or equal to 10 nm and less than or equal to 200 nm, and a height of the structure body is greater than or equal to 5 nm and less than or equal to 100 nm.

Alternatively, another embodiment of the present invention is the method for fabricating an organic semiconductor device with the above structure, in which a width of the structure body is greater than or equal to 100 nm and less than or equal to 150 nm, and a height of the structure body is greater than or equal to 20 nm and less than or equal to 60 nm.

Alternatively, another embodiment of the present invention is the method for fabricating an organic semiconductor device with the above structure, in which a density of the structure body is greater than or equal to 0.1/μm² and less than or equal to 0.5/μm².

Alternatively, another embodiment of the present invention is the method for fabricating an organic semiconductor device with the above structure, in which the material included in the second layer includes an organometallic complex.

Alternatively, another embodiment of the present invention is the method for fabricating an organic semiconductor device with the above structure, in which the material included in the second layer has an electron-transport property.

Alternatively, another embodiment of the present invention is the method for fabricating an organic semiconductor device with the above structure, in which the material included in the second layer has a π-electron deficient heterocycle in its molecular structure.

Alternatively, another embodiment of the present invention is the method for fabricating an organic semiconductor device with the above structure, in which the material included in the second layer has an electron-withdrawing substituent in its molecular structure.

Alternatively, another embodiment of the present invention is the method for fabricating an organic semiconductor device with the above structure, in which the third layer is a layer including an inorganic compound.

Alternatively, another embodiment of the present invention is the method for fabricating an organic semiconductor device with the above structure, in which the third layer is one or more selected from aluminum, indium, tungsten, molybdenum, gallium, zinc, silicon, and an oxide or a nitride thereof.

Alternatively, another embodiment of the present invention is the method for fabricating an organic semiconductor device with the above structure, in which the third layer is a layer including aluminum oxide.

Alternatively, another embodiment of the present invention is the method for fabricating an organic semiconductor device with the above structure, in which the third layer is formed by an atomic layer deposition (ALD) method.

Alternatively, another embodiment of the present invention is a method for fabricating a light-emitting device with the above structure, in which the first layer includes a light-emitting layer.

Alternatively, another embodiment of the present invention is the method for fabricating a light-emitting device with the above structure, in which the first layer has a stacked-layer structure and the first layer includes a hole-injection layer, a hole-transport layer, the light-emitting layer, and an electron-transport layer in this order from the first electrode side.

Alternatively, another embodiment of the present invention is a method for fabricating a photosensor with the above structure, in which the first layer includes a photoelectric conversion layer.

Alternatively, another embodiment of the present invention is a method for fabricating an organic transistor with the above structure, in which the first layer includes an active layer.

Alternatively, another embodiment of the present invention is the method for fabricating an organic semiconductor device with the above structure, in which the second layer is formed by a vacuum evaporation method.

Note that the light-emitting apparatus in this specification includes, in its category, an image display device that uses an organic EL device. The light-emitting apparatus may also include a module in which an organic EL device is provided with a connector such as an anisotropic conductive film or a TCP (Tape Carrier Package), a module in which a printed wiring board is provided at the end of a TCP, and a module in which an IC (integrated circuit) is directly mounted on an organic EL device by a COG (Chip On Glass) method. Furthermore, a lighting device or the like may include the light-emitting apparatus.

### Effect of the Invention

One embodiment of the present invention can provide a method for fabricating an organic semiconductor device capable of inhibiting generation of defects. Another embodiment of the present invention can provide a method for fabricating an organic semiconductor device applicable to a high-resolution organic semiconductor apparatus and capable of inhibiting generation of defects. Another embodiment of the present invention can provide a method for fabricating an organic semiconductor device capable of fabricating an organic semiconductor device with favorable characteristics. Another embodiment of the present invention can provide a method for fabricating an organic semiconductor device with favorable yield.

Note that the description of these effects does not preclude the existence of other effects. Note that one embodiment of the present invention does not need to have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A and FIG. 1B are schematic views of organic semiconductor layers, structure body layers, and protective layers.

FIG. 2A and FIG. 2B are schematic views of organic semiconductor layers, structure body layers, and protective layers.

FIG. 3A to FIG. 3E are diagrams illustrating a method for processing an organic semiconductor layer.

FIG. 4A to FIG. 4D are diagrams illustrating a method for processing an organic semiconductor layer.

FIG. 5A to FIG. 5C are schematic views each illustrating an organic semiconductor device.

FIG. 6A and FIG. 6B are schematic views illustrating an organic semiconductor apparatus.

FIG. 7A to FIG. 7E are diagrams illustrating a method for fabricating an organic semiconductor apparatus.

FIG. 8A to FIG. 8D are diagrams illustrating a method for fabricating an organic semiconductor apparatus.

FIG. 9A to FIG. 9D are diagrams illustrating a method for fabricating an organic semiconductor apparatus.

FIG. 10A to FIG. 10C are diagrams illustrating a method for fabricating an organic semiconductor apparatus.

FIG. 11A to FIG. 11C are diagrams illustrating a method for fabricating an organic semiconductor apparatus.

FIG. 12A to FIG. 12C are diagrams illustrating a method for fabricating an organic semiconductor apparatus.

FIG. 13 is a schematic view of a light-emitting device.

FIG. 14A and FIG. 14B are perspective views illustrating a structure example of a display module.

FIG. 15A and FIG. 15B are cross-sectional views illustrating structure examples of a display apparatus.

FIG. 16 is a perspective view illustrating a structure example of a display apparatus.

FIG. 17 is a cross-sectional view illustrating a structure example of a display apparatus.

FIG. 18 is a cross-sectional view illustrating a structure example of a display apparatus.

FIG. 19 is a cross-sectional view illustrating a structure example of a display apparatus.

FIG. 20A to FIG. 20D are diagrams each illustrating an example of an electronic appliance.

FIG. 21A to FIG. 21F are diagrams each illustrating an example of an electronic appliance.

FIG. 22A to FIG. 22G are diagrams each illustrating an example of an electronic appliance.

FIG. 23A and FIG. 23B are critical dimension SEM images of samples including structure body layers of Structure 1 and Structure 5.

FIG. 24A and FIG. 24B are cross-sectional TEM images of samples including structure body layers of Structure 1 and Structure 5.

FIG. 25 are optical micrographs and cross-sectional TEM images of samples including structure body layers of Structure 2 to Structure 4.

### MODE FOR CARRYING OUT THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In this specification and the like, a device fabricated using a metal mask or an FMM (fine metal mask, high-resolution metal mask) may be referred to as a device having an MM (metal mask) structure. In addition, in this specification and the like, a device fabricated without using a metal mask or an FMM may be referred to as a device having an MML (Metal-Maskless Lithography) structure.

In this specification and the like, a film that is not processed into any shape after being formed is referred to as a “film”, and a film that is processed into a shape after being formed is referred to as a “layer” in many cases. However, they are distinguished mainly for easy understanding of the progress of the process, and there is no big difference between them, whereby a “film” can be read as a “layer”, and a “layer” can be read as a “film”. In particular, both of them have the same meaning in a description that does not refer to a processing step.

### Embodiment 1

As a method for fabricating an organic semiconductor film in a predetermined shape, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the mask and the substrate. Meanwhile, shape processing of an organic semiconductor film by a photolithography method enables the formation of a finer pattern. The processing of an organic semiconductor film by a photolithography method can also achieve an increase in area easily and thus has been actively researched.

However, the shape processing of an organic semiconductor film by a photolithography method requires many problems to be overcome. Examples of these problems include the influence of the following: exposure of the organic semiconductor film to the air, light irradiation in exposure of a photosensitive resin to light, and a developer used in developing the light-exposed photosensitive resin.

The influence of the above is considered problematic because it eliminates the organic semiconductor film itself, or damages a surface of the organic semiconductor film to significantly degrade the characteristics of a device to be fabricated later, for example.

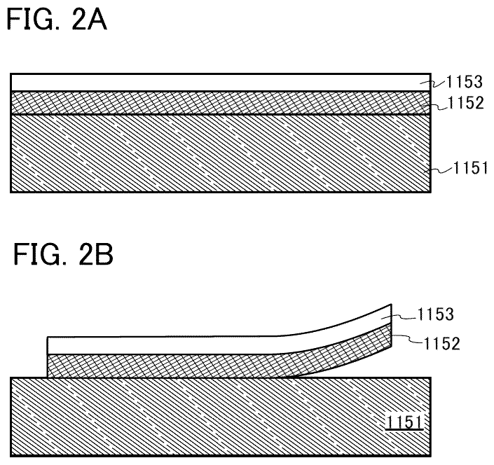

In order to reduce such an adverse effect, a protective layer 1152 is sometimes provided over an organic semiconductor film 1151 in processing by a photolithography method as illustrated in FIG. 2A. Note that a layer 1153 to be a mask (hereinafter sometimes referred to as the mask layer 1153) is preferably formed over the protective layer. When a photolithography step is performed after the protective layer 1152 or the mask layer 1153 is provided, the influence of light irradiation and the influence of a developer in processing the photosensitive resin can be reduced.

The protective layer 1152 needs to have low selectivity with respect to etching in performing shape processing of the organic semiconductor film 1151. Thus, the protective layer 1152 is preferably a layer having characteristics different from those of the organic semiconductor film 1151. A typical example of a material having characteristics different from those of the organic semiconductor film 1151, which is an organic compound, is an inorganic compound. In forming and performing shape processing of the protective layer 1152, damage to the organic semiconductor film 1151 is preferably small.

However, in the case where the protective layer 1152 including the material having characteristics different from those of the organic semiconductor film 1151 is provided over the organic semiconductor film 1151, adhesion is low in principle in many cases; thus, separation (also referred to as peeling) might occur between the organic semiconductor film and the protective layer as illustrated in FIG. 2B. In particular, a film formed under a mild condition (e.g., a film formed by an atomic layer deposition (ALD) method) is dense but has low adhesion to a film serving as a base (the organic semiconductor film) in some cases, which tends to cause peeling.

When the protective layer 1152 is peeled, normal patterning of the organic semiconductor film cannot be performed, which directly leads to generation of defects. Thus, a decrease in yield can be inhibited by inhibiting peeling of the protective layer 1152.

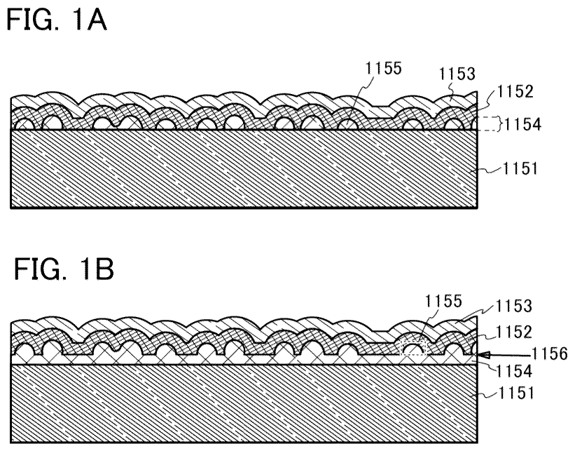

Here, before the protective layer 1152 is provided over the organic semiconductor film 1151, a layer (a structure body layer 1154) including a material forming a structure body 1155 having a projecting shape as illustrated in FIG. TA and FIG. 1B is provided and the protective layer 1152 is provided thereover, whereby peeling of the protective layer 1152 and generation of defects can be inhibited. In one embodiment of the present invention, the structure body 1155 is an island-shaped object including a material different from that of the organic semiconductor film 1151 provided over the organic semiconductor film 1151 or a surface 1156 of the structure body layer 1154. Having a projecting shape means that the structure body 1155 has a height with respect to a formation surface of the structure body 1155, and the number of height peaks of the structure body 1155 is not limited to one. That is, the structure body 1155 may have a plurality of peaks or may have a depression and a projection with a valley or a hole. The formation surface of the structure body 1155 is the surface of the organic semiconductor film 1151 or the surface 1156 excluding the structure body 1155 portion of the structure body layer 1154. Note that even in the case where the structure body 1155 is provided in an island shape and not in a layered shape, the whole structure body is referred to as the structure body layer 1154 for convenience.

The structure body layer 1154 is formed using a material that forms the structure body 1155 having a projecting shape with a width greater than or equal to 10 nm and less than or equal to 200 nm, preferably greater than or equal to 80 nm and less than or equal to 150 nm, further preferably greater than or equal to 100 nm and less than or equal to 150 nm, and a height greater than or equal to 5 nm and less than or equal to 100 nm, preferably greater than or equal to 20 nm and less than or equal to 80 nm, further preferably greater than or equal to 20 nm and less than or equal to 60 nm when film formation by evaporation is performed.

Note that in this specification, the width of the structure body 1155 means the distance between two points on an outline of the structure body 1155 at a position where the distance between the two points is the largest when the structure body 1155 is seen in the direction perpendicular to an electrode surface. Alternatively, the width of the structure body 1155 means the largest distance, in the case where a line substantially parallel to the electrode is considered in a cross-sectional view of the structure body 1155, between the outlines of the structure body on the line.

The density of the structure body 1155 is preferably greater than or equal to 0.01/μm², further preferably greater than or equal to 0.1/μm². Furthermore, the density of the structure body 1155 is preferably less than or equal to 50/μm², further preferably less than or equal to 5/μm². Note that in the case of a high-resolution semiconductor apparatus with a resolution higher than or equal to 200 ppi, the density of the structure body 1155 is preferably greater than or equal to 0.05/μm² and less than or equal to 1/μm², further preferably greater than or equal to 0.1/μm² and less than or equal to 0.5/μm².

The structure body layer 1154 is preferably formed using an organic compound or an organometallic complex having a glass transition temperature lower than or equal to 120 °C. With use of an organic compound or an organometallic complex having a glass transition temperature lower than or equal to 120 °C, crystallization partly occurs in film formation, so that a projecting structure body can be formed.

The structure body layer 1154 is preferably formed using an organic compound or an organometallic complex whose crystallization temperature is observed in one or both of a temperature rising step and a temperature decreasing step in differential scanning calorimetry. An organic compound or an organometallic complex whose crystallization temperature is observed in one or both of a temperature rising step and a temperature decreasing step in differential scanning calorimetry is used, whereby crystallization partly occurs in film formation, enabling formation of a projecting structure body.

It is preferable that the structure body layer 1154 include a material having a π-electron deficient heterocycle in its molecular structure, a material having an electron-withdrawing group in its molecular structure, or a material having an electron-transport property, in which case an organic semiconductor device with favorable characteristics can be obtained. In general, the next step is performed after the removal of the structure body layer 1154 from the upper surface of the organic semiconductor layer; however, the structure body layer 1154 is not completely removed and remains over an organic semiconductor layer 1151a in some cases. When the structure body layer 1154 includes a material having a π-electron deficient heterocycle in its molecular structure or a material having an electron-withdrawing group in its molecular structure or has an electron-transport property, even the residue of the structure body layer 1154 over the organic semiconductor layer 1151a due to incomplete removal does not degrade characteristics of the organic semiconductor device.

In the case where the structure body layer 1154 includes a material having a π-electron deficient heterocycle in its molecular structure, specific examples of the π-electron deficient heterocycle include pyridine, pyrazine, pyrimidine, pyridazine, quinoline, quinolinol, isoquinoline, isoquinolinol, quinoxaline, quinazoline, azatriphenylene, dibenzoquinoxaline, dibenzoquinazoline, triazatriphenylene, tetraazatriphenylene, pentaazatriphenylene, and hexaazatriphenylene. Other examples include a condensed ring in which two or more of the π-electron deficient heterocycles are condensed and a condensed ring in which two or more of the π-electron deficient heterocycles and a benzene ring are condensed.

In the case where the material included in the structure body layer 1154 includes a material having an electron-withdrawing group, the electron-withdrawing group refers specifically to a halogen, a substituted or unsubstituted alkyl halide group having 1 to 6 carbon atoms, a substituted or unsubstituted alkoxy group having 1 to 6 carbon atoms, a substituted or unsubstituted alkoxy halide group having 1 to 6 carbon atoms, a cyano group, a nitro group, a carbonyl group, a carboxylic acid group, or the like.

As specific materials included in the structure body layer 1154, organic compounds represented by General Formula (G1) to General Formula (G4) below can be suitably used, in addition to an organometallic complex such as (8-quinolinolato)lithium (abbreviation: Liq), tris(8-quinolinolato)aluminum (abbreviation: Alq₃), bis(2-methyl-8-quinolinolato)(4-phenylphenolato)aluminum(III) (abbreviation: BAlq), (8-quinolinolato)sodium (abbreviation: Naq), (8-quinolinolato)potassium (abbreviation: Kq), bis(8-quinolinolato)zinc (abbreviation: Znq2), bis(8-quinolinolato)copper(II) (abbreviation: Cuq₂), tris(8-quinolinolato)cobalt(III) (abbreviation: Coq₃), tris(8-quinolinolato)gallium(III) (abbreviation: Gaq₃), and tetrakis(8-quinolinolato)zirconium(VI) (abbreviation: Zrq₄).

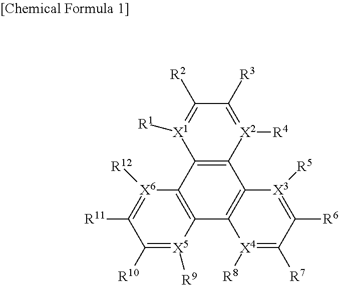

Note that in the organic compound represented by General Formula (G1) above, X¹ to X⁶ each independently represent a carbon atom or a nitrogen atom. Furthermore, R¹ to R¹² each independently represent any of hydrogen, halogen, a substituted or unsubstituted alkyl halide group having 1 to 6 carbon atoms, a substituted or unsubstituted alkoxy group having 1 to 6 carbon atoms, a substituted or unsubstituted alkoxy halide group having 1 to 6 carbon atoms, a cyano group, a nitro group, a carbonyl group, and a carboxylic acid group; and adjacent substituents may be bonded to each other to form a ring. Note that when X¹ to X⁶ each represent nitrogen, R¹, R⁴, R⁵, R⁸, R⁹, and R¹² corresponding to X¹ to X⁶ are ignored because nitrogen does not have hydrogen and a substituent. When R¹ to R¹² each represent a carboxylic acid group, dehydration condensation may occur between adjacent carboxylic acid groups and they may form an acid anhydride ring.

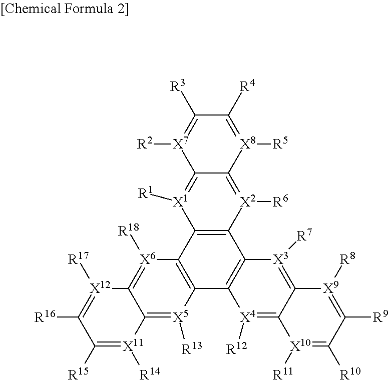

Note that in the organic compound represented by General Formula (G2) above, X¹ to X¹² each independently represent a carbon atom or a nitrogen atom. Furthermore, R¹ to R¹⁸ each independently represent any of hydrogen, halogen, a substituted or unsubstituted alkyl halide group having 1 to 6 carbon atoms, a substituted or unsubstituted alkoxy group having 1 to 6 carbon atoms, a substituted or unsubstituted alkoxy halide group having 1 to 6 carbon atoms, a cyano group, a nitro group, a carbonyl group, and a carboxylic acid group; and adjacent substituents may be bonded to each other to form a ring. Note that when X¹ to X¹² each represent nitrogen, R¹, R², R⁵ to R⁸, R¹¹ to R¹⁴, R¹⁷, and R¹⁸ corresponding to X¹ to X¹² are ignored because nitrogen does not have hydrogen and a substituent. When R¹ to R¹⁸ each represent a carboxylic acid group, dehydration condensation may occur between adjacent carboxylic acid groups and they may form an acid anhydride ring.

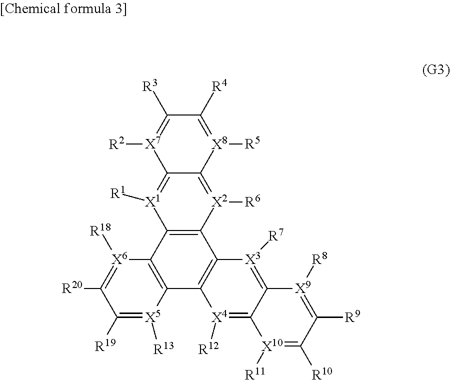

Note that in the organic compound represented by General Formula (G3) above, X¹ to X¹⁰ each independently represent a carbon atom or a nitrogen atom. Furthermore, R¹ to R¹³ and R¹⁸ to R²⁰ each independently represent any of hydrogen, halogen, a substituted or unsubstituted alkyl halide group having 1 to 6 carbon atoms, a substituted or unsubstituted alkoxy group having 1 to 6 carbon atoms, a substituted or unsubstituted alkoxy halide group having 1 to 6 carbon atoms, a cyano group, a nitro group, a carbonyl group, and a carboxylic acid group; and adjacent substituents may be bonded to each other to form a ring. Note that when X¹ to X¹⁰ each represent nitrogen, R¹, R², R⁵ to R⁸, R¹¹ to R¹³, and R¹⁸ corresponding to X¹ to X¹⁰ are ignored because nitrogen does not have hydrogen and a substituent. When R¹ to R¹³ and R¹⁸ to R²⁰ each represent a carboxylic acid group, dehydration condensation may occur between adjacent carboxylic acid groups and they may form an acid anhydride ring.

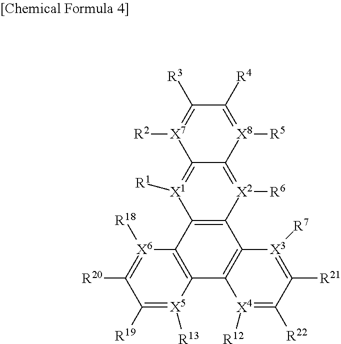

Note that in the organic compound represented by General Formula (G4) above, X¹ to X⁸ each independently represent a carbon atom or a nitrogen atom. Furthermore, R¹ to R⁷, R¹², R¹³, and R¹⁸ to R²² each independently represent any of hydrogen, halogen, a substituted or unsubstituted alkyl halide group having 1 to 6 carbon atoms, a substituted or unsubstituted alkoxy group having 1 to 6 carbon atoms, a substituted or unsubstituted alkoxy halide group having 1 to 6 carbon atoms, a cyano group, a nitro group, a carbonyl group, and a carboxylic acid group; and adjacent substituents may be bonded to each other to form a ring. Note that when X¹ to X⁸ each represent nitrogen, R¹, R², R⁵ to R⁷, R¹², R¹³, and R¹⁸ corresponding to X¹ to X⁸ are ignored because nitrogen does not have hydrogen and a substituent. When R¹ to R⁷, R¹², R¹³, and R¹⁸ to R²² each represent a carboxylic acid group, dehydration condensation may occur between adjacent carboxylic acid groups and they may form an acid anhydride ring.

Among the organic compounds represented by General Formulae (G1) to (G4) above, it is preferable to use an organic compound with a dipole moment less than 20 Debye because in that case, aggregation of the organic compound easily occurs and the structure body is easily formed, and it is particularly preferable to use an organic compound with a dipole moment less than 11 Debye. Furthermore, among the organic compounds represented by General Formulae (G1) to (G4) above, a compound in which the crystallization temperature is observed in DSC (Differential Scanning Calorimetry) is preferably used because in that case, the structure body is easily formed. In the case where the glass transition point is observed, the glass transition point is preferably less than 120 °C because in that case, the structure body is easily formed. Furthermore, it is preferable that in TG-DTA (Thermogravimetry-Differential Thermal Analysis), thermal behavior of melting be not observed at a temperature lower than a temperature at which the mass changes and the mass change occur due to sublimation because in that case, the structure body is easily formed; the TG-DTA is preferably performed in the range from an atmospheric pressure to 1×10⁻⁴ Pa, further preferably performed under a reduced pressure (less than or equal to 10 Pa) as in the case of forming a thin film.

Examples of the organic compounds represented by the above general formulae include organic compounds represented by Structural Formulae (1) to (40) below.

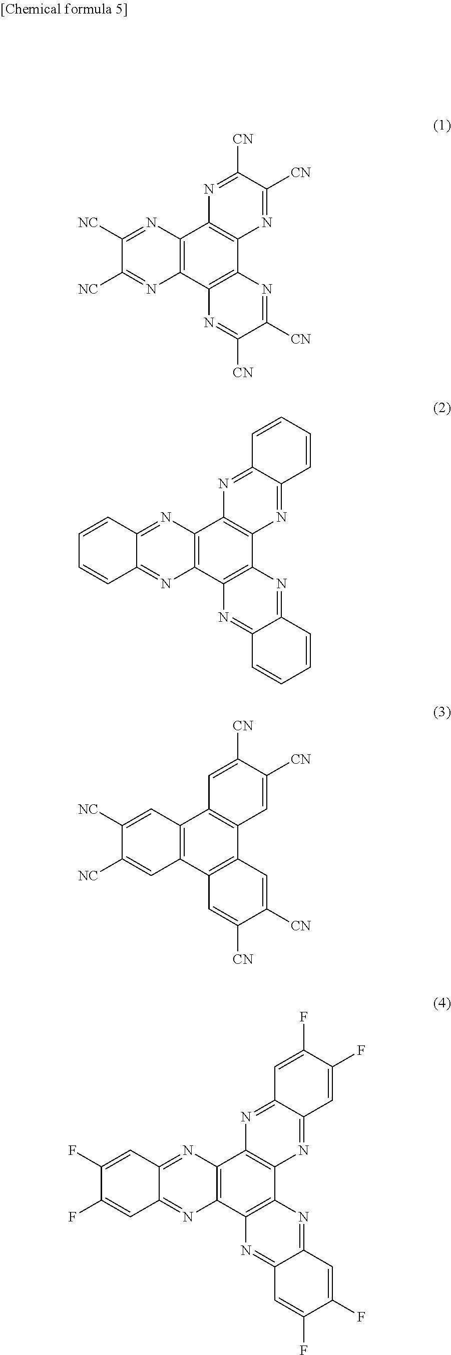

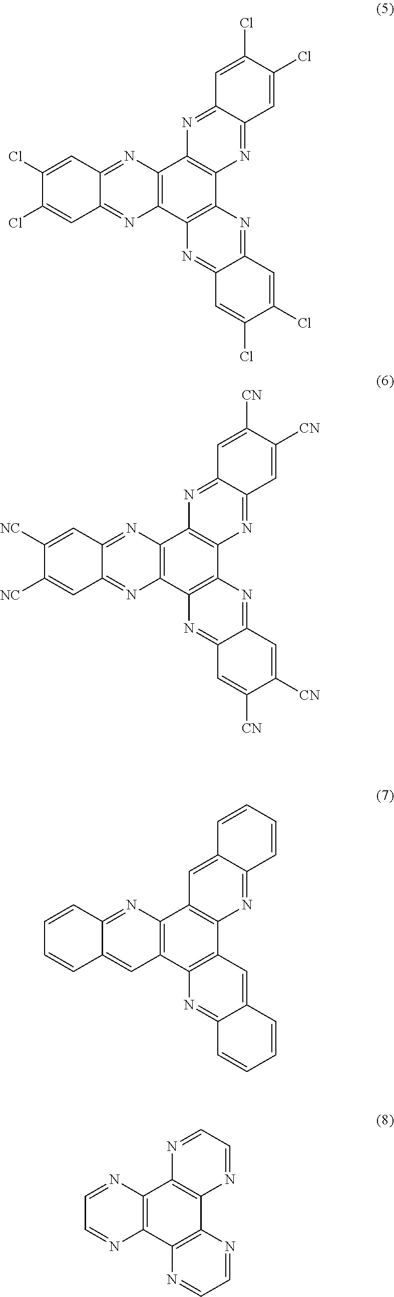

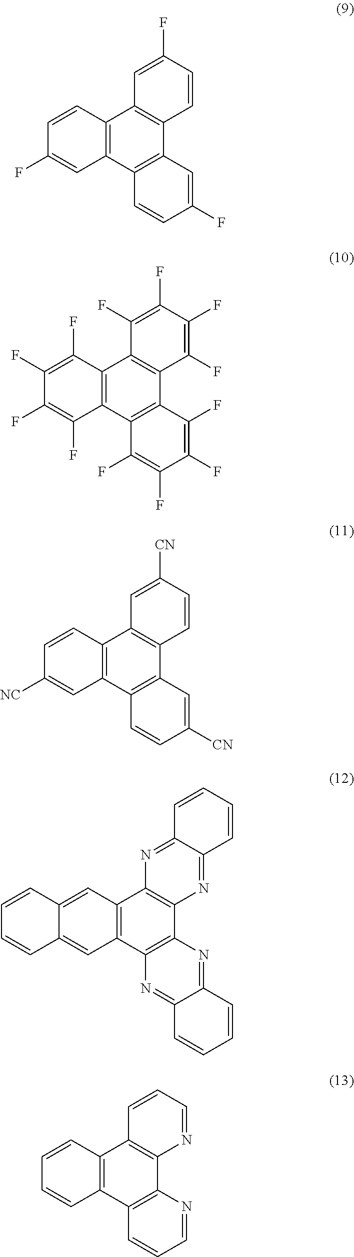

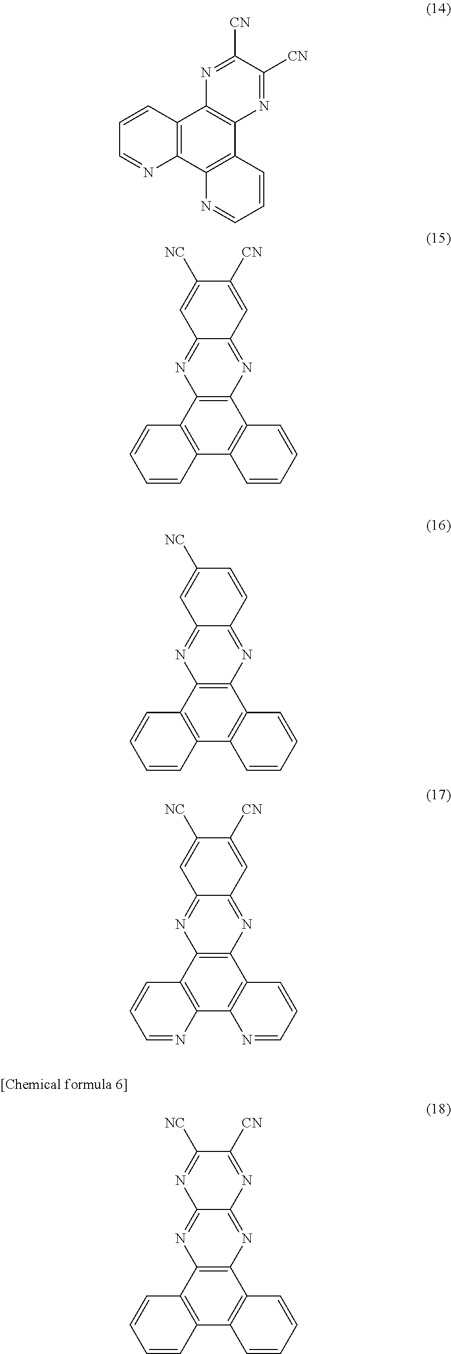

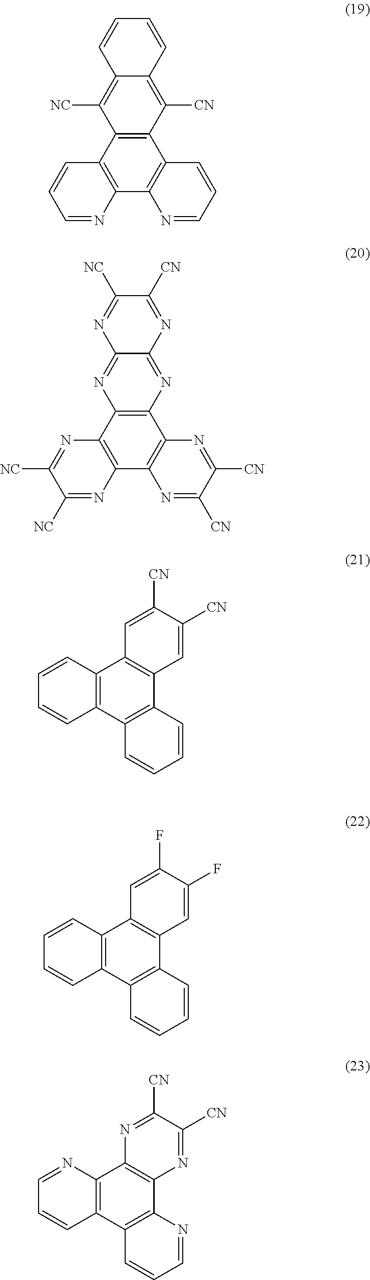

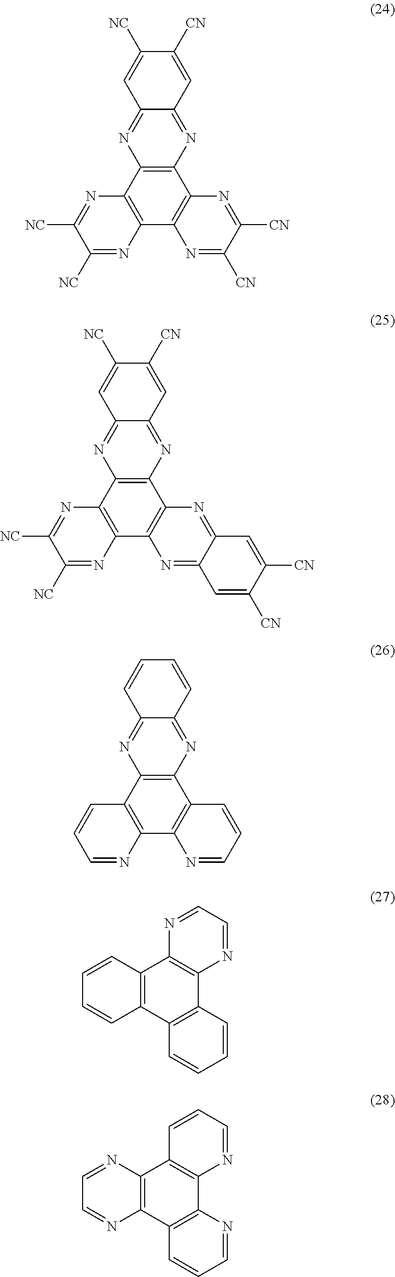

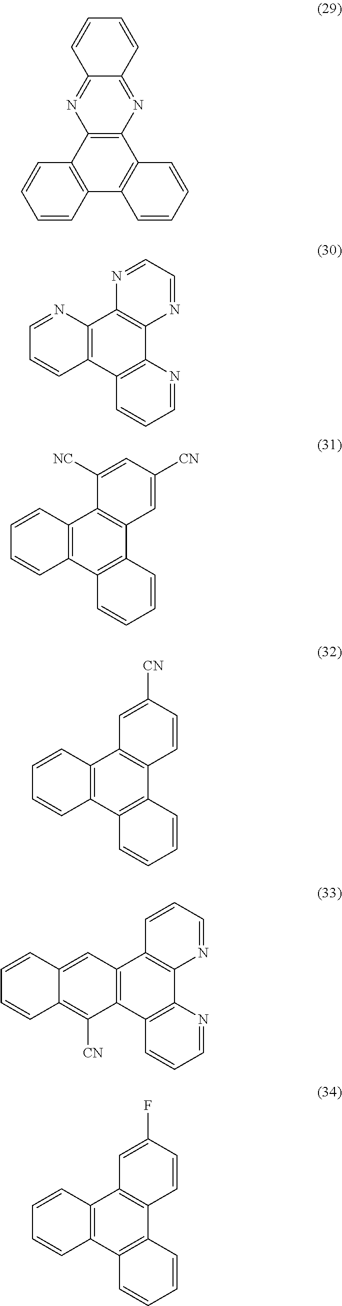

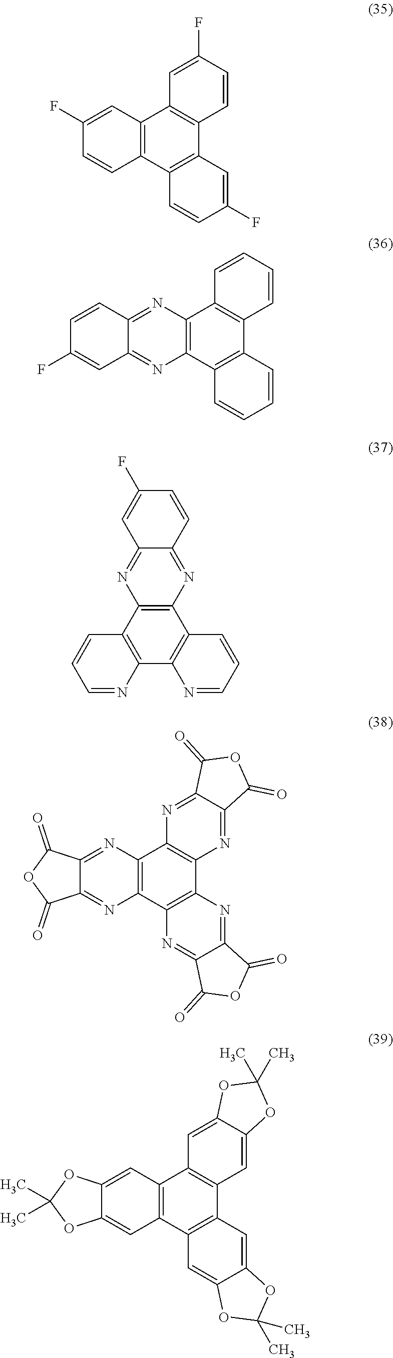

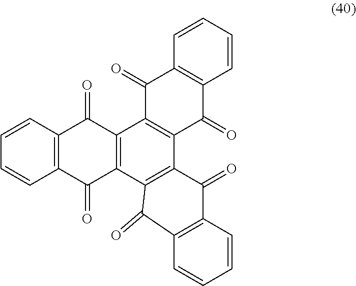

In the organic compound represented by any of General Formulae (G1) to (G4) above, a film corresponding to a thickness of 1 nm to 30 nm is formed over an active layer by a vacuum evaporation method, whereby the above structure body 1155 is formed. Note that a material for forming the above structure body 1155 does not form a flat film. Thus, the deposition amount of the structure body is determined using a given material forming a flat film as a reference material. For example, 4,4′-bis[N-(1-naphthyl)-N-phenylamino]biphenyl (abbreviation: NPB) is used as the reference material, and a film is formed using a calibration curve of NPB. The use of the calibration curve of the same substance every time makes it possible to control a deposition amount even though a correct deposition amount is not clear. In this consideration, NPB is used as the reference material, and the organic compound represented by any of General Formulae (G1) to (G4) is deposited with the amount corresponding to the NPB thickness of 1 nm to 30 nm, whereby the above structure body is formed. That is, the deposition amount corresponding to the thickness of 1 nm to 30 nm can be represented as the deposition amount corresponding to the NPB thickness of 1 nm to 30 nm accurately.

When the above-described structure body layer 1154 is provided, the projection portion of the structure body 1155 increases the contact area with the film formation surface of the protective layer 1152. This can inhibit peeling of the protective layer 1152.

The protective layer 1152 preferably has low selectivity with respect to etching in performing shape processing of the organic semiconductor layer, as described above. That is, the protective layer 1152 is preferably a layer having characteristics different from those of the organic semiconductor layer. A typical example of a material having characteristics different from those of the organic semiconductor, which is an organic compound, is an inorganic compound. Specific examples include a metal material such as aluminum, indium, tungsten, titanium, molybdenum, tantalum, gallium, and zinc, a nonmetallic inorganic material such as silicon, and an alloy and a compound containing any of these. Specific examples of the compounds and the alloys include aluminum oxide, silicon nitride, silicon oxide, tantalum nitride, an alloy containing molybdenum and niobium, an alloy containing molybdenum and tungsten, indium gallium zinc oxide (also referred to as In—Ga—Zn oxide or IGZO), indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), and indium gallium tin zinc oxide (In—Ga—Sn—Zn oxide). Alternatively, indium tin oxide containing silicon or the like can also be used. It is particularly preferable that aluminum oxide, IGZO, molybdenum oxide, or the like be used in the protective layer.

Among these, it is further preferable that a material that allows the use of a film formation method that causes less damage to the organic semiconductor layer during film formation, such as an ALD method or a chemical vapor deposition (CVD) method, be employed. The protective layer is further preferably formed using a material that allows the protective layer to be processed and removed by a film formation method that causes less damage to the organic semiconductor layer. Note that a film formation method such as a sputtering method may be used to form the protective layer.

Note that an aluminum oxide film formed by an ALD method is particularly suitable as the protective layer because the aluminum oxide film is dense and has a high barrier property, and less damage is caused to the organic semiconductor layer in film formation, shape processing, and removal. On the other hand, the aluminum oxide film formed by an ALD method sometimes has a mild film formation condition and tends to have low adhesion to the organic semiconductor layer. Accordingly, an embodiment using the aluminum oxide protective layer formed by an ALD method is an embodiment in which the effect of providing the structure body layer is particularly high. A silicon nitride film formed by a CVD method is also a film suitable for the protective layer.

As the mask layer formed over the protective layer, a material that is different from that for the protective layer can be selected from any of the materials that can be used for the protective layer. The mask layer is preferably formed using a material that has a processing method with high selectivity with respect to the protective layer. Note that since the mask layer is formed over the protective layer, the influence of the mask layer on the organic semiconductor layer in film formation is small. This allows for a wider selection of film formation methods for the mask layer. Among the above-described materials, tungsten, molybdenum, IGZO, or the like is particularly preferable for the mask layer. Films of these materials can be formed by a sputtering method.

The above-described method for fabricating the organic semiconductor device by which processing is performed by a photolithography method using the structure body layer, the protective layer, and the mask layer can be a fabrication method with a low incidence of defects and high yield. As a result, the organic semiconductor device fabricated by the fabrication method can be an inexpensive organic semiconductor device.

Note that the protective layer and the mask layer may each be formed as a single layer or a plurality of layers.

The structure of this embodiment can be used in combination with any of the other structures as appropriate.

### Embodiment 2

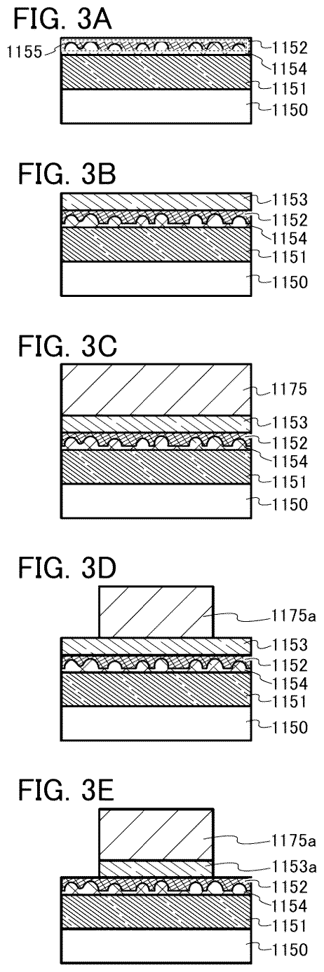

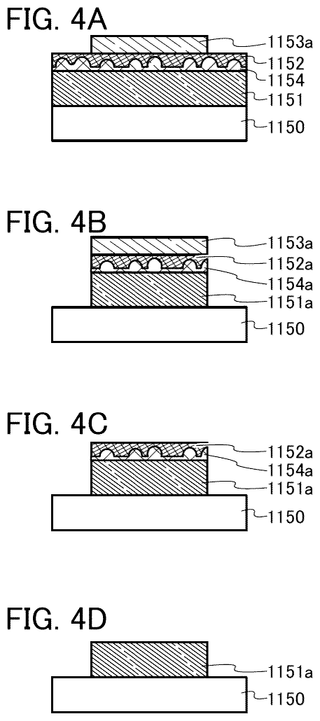

In this embodiment, a method for processing an organic semiconductor layer of one embodiment of the present invention is described with reference to FIG. 3 and FIG. 4.

First, the organic semiconductor film 1151 is formed over a base film 1150 (FIG. 3A). The base film may be either an insulating film or a conductive film depending on a device fabricated later. The organic semiconductor film 1151 may be formed by a dry method such as an evaporation method or a wet method such as a spin coating method.

Next, over the organic semiconductor film 1151, the structure body layer 1154 is formed using the material given in Embodiment 1 (FIG. 3A). The structure body layer 1154 is formed by a vacuum evaporation method, and performing evaporation forms the structure body 1155.

Next, the protective layer 1152 is formed over the structure body layer 1154 (FIG. 3A). The protective layer 1152 can be formed using the material described in Embodiment 1. The protective layer 1152 is preferably a dense film having a high barrier property, and an aluminum oxide film is preferably formed by an ALD method. Although the aluminum oxide film formed by an ALD method is preferable because less damage is caused to a base, adhesion to the organic semiconductor film 1151 is weak; thus, the aluminum oxide film formed by an ALD method is the structure where the effect of providing the structure body layer 1154 is large. Furthermore, IGZO is also preferably used for the protective layer 1152.

The mask layer 1153 is preferably formed over the protective layer 1152 (FIG. 3B). Since damage to the organic semiconductor film 1151 can be inhibited by the structure body layer 1154 and the protective layer 1152, a film formation method that causes relatively large damage to a surface over which a film is formed, such as a sputtering method, is easily selected for the formation of the mask layer 1153. Examples of a material forming the mask layer 1153 include silicon, silicon nitride, silicon oxide, tungsten, titanium, molybdenum, tantalum, tantalum nitride, an alloy containing molybdenum and niobium, or an alloy metal oxide containing molybdenum and tungsten, and a metal oxide such as an indium gallium zinc oxide (also denoted as In—Ga—Zn oxide or IGZO). It is also possible to use indium oxide, an indium zinc oxide (In—Zn oxide), an indium tin oxide (In—Sn oxide), an indium titanium oxide (In—Ti oxide), an indium tin zinc oxide (In—Sn—Zn oxide), an indium titanium zinc oxide (In—Ti—Zn oxide), an indium gallium tin zinc oxide (In—Ga—Sn—Zn oxide), or the like. Alternatively, indium tin oxide containing silicon or the like can also be used.

Then, a photosensitive resin is applied over the mask layer 1153 to form a resin film 1175 (FIG. 3C). The photosensitive resin may be either a positive type resist or a negative type resist.

Next, a photomask layer 1175a is formed by performing light exposure in accordance with the photosensitivity of the resin and performing development (FIG. 3D), and the mask layer 1153 is etched using the photomask layer 1175a to form a mask layer 1153a (FIG. 3E). The mask layer 1153 may be etched by either wet etching or dry etching. For the etching, a condition where the mask layer 1153 has a higher selectivity with respect to the protective layer 1152 is preferably selected.

After the mask layer 1153a is formed, the photomask layer 1175a is removed (FIG. 4A). Owing to the mask layer 1153 and the protective layer 1152, the organic semiconductor film 1151 is prevented from being adversely affected, for example, being eliminated or being damaged, by treatment in forming and removing the photomask layer 1175a, and thus, an organic semiconductor device having favorable characteristics can be fabricated.

Here, the protective layer 1152 can be etched at the same time as the photomask layer 1175a depending on a chemical solution for removing the photomask layer 1175a. However, in this step, peeling is likely to occur between the protective layer 1152 and the organic semiconductor film 1151 in the case where the structure body layer 1154 is not formed. In one embodiment of the present invention, the formation of the structure body layer 1154 can inhibit occurrence of peeling and prevent defects even in the case where the photomask layer 1175a and the protective layer 1152 are etched at the same time.

After that, etching is performed using the mask layer 1153a as a mask, so that the organic semiconductor layer 1151a, a structure body layer 1154a, and a protective layer 1152a are formed (FIG. 4B). This etching may be either wet etching or dry etching, but dry etching is preferable.

After the processing of the organic semiconductor layer 1151a is completed, the mask layer 1153a is removed (FIG. 4C). The mask layer 1153a can be removed by either wet etching or dry etching, but dry etching is preferable. For the etching, a condition where the mask layer 1153a has a higher selectivity with respect to the protective layer 1152a is preferably selected.

Finally, the protective layer 1152a and the structure body layer 1154a are removed (FIG. 4D). The mask layer 1153a and the structure body layer 1154a can be removed by either wet etching or dry etching, but wet etching is preferable. For the etching, a condition where the protective layer 1152a and the structure body layer 1154a have high selectivity with respect to the organic semiconductor layer 1151a is preferably selected.

For the organic semiconductor layer 1151a processed through the above steps, peeling of the protective layer 1152 is inhibited, so that the organic semiconductor layer 1151a can be easily processed into a desired shape. As a result, the organic semiconductor device and the organic semiconductor apparatus using the organic semiconductor layer 1151a processed through the above steps can be manufactured with high yield and can be fabricated at low cost.

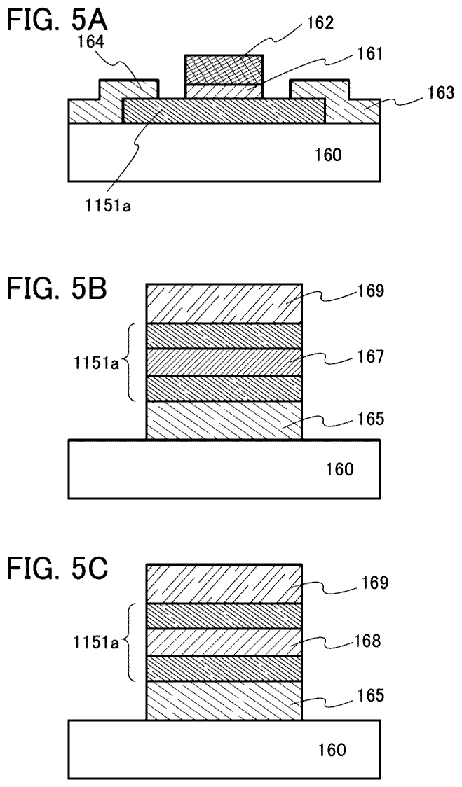

As illustrated in FIG. 5A, the organic semiconductor layer 1151a can be used for an organic TFT including, over an insulating layer 160, the organic semiconductor layer 1151a, agate insulating layer 161, a gate electrode 162, a source and a drain electrode 163 and 164. As illustrated in FIG. 5B, the organic semiconductor layer 1151a can be used for a photoelectric conversion device such as a solar cell or a photosensor, including, over the insulating layer 160, a first electrode 165, a second electrode 169, and a photoelectric conversion layer 167. As illustrated in FIG. 5C, the organic semiconductor layer 1151a can be used for an organic EL device including, over the insulating layer 160, the first electrode 165, the second electrode 169, and a light-emitting layer 168.

The structure of this embodiment can be used in combination with any of the other structures as appropriate.

### Embodiment 3

In this embodiment, a method for fabricating the organic semiconductor device of one embodiment of the present invention is described using a method for fabricating a display apparatus (a display apparatus including an organic EL device) as an example.

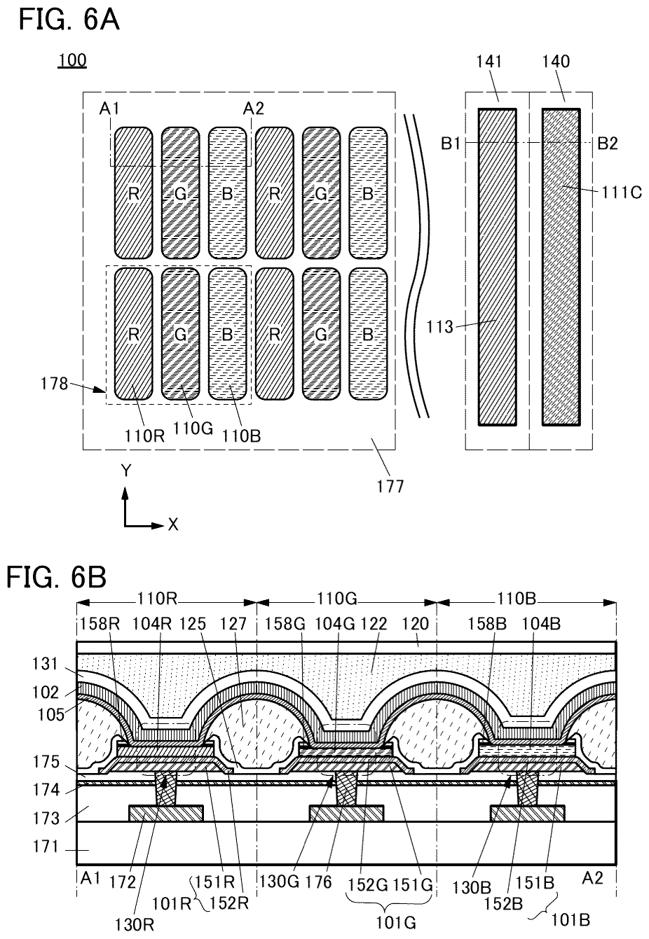

As illustrated in FIG. 6A and FIG. 6B, a plurality of light-emitting devices 130 are formed over the insulating layer 175 to constitute a display apparatus 100.

The display apparatus includes a pixel portion 177 in which a plurality of pixels 178 are arranged in matrix. The pixel 178 includes a subpixel 110R, a subpixel 110G, and a subpixel 110B.

In this specification and the like, for example, description common to the subpixel 110R, the subpixel 110G, and the subpixel 110B is sometimes made using the term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 1101B emits blue light. Thus, an image can be displayed on the pixel portion 177. Note that in this embodiment, description is made using subpixels of three colors of red (R), green (G), and blue (B) as examples; however, subpixels of a different combination of colors may be employed. The number of subpixels is not limited to three, and may be four or more. Examples of four subpixels include subpixels of four colors of R, G, B, and white (W), subpixels of four colors of R, G, B, and Y, and four subpixels of R, G, B, and infrared light (IR). In addition, a sensor may be provided in the pixel 178. Part of a layer that transports carriers in an organic photodiode sensor including an organic compound can be formed using the same material as the light-emitting device.

In this specification and the like, the row direction and the column direction are sometimes referred to as the X direction and the Y direction, respectively. The X direction and the Y direction intersect with each other and are perpendicular to each other, for example.

FIG. 6A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 111C is provided in the connection portion 140.

Although FIG. 6A illustrates an example where the region 141 and the connection portion 140 are positioned on the right side of the pixel portion 177, the positions of the region 141 and the connection portion 140 are not particularly limited. The number of regions 141 and the number of connection portions 140 can each be one or more.

FIG. 6B is an example of a cross-sectional view along the dashed-dotted line A1-A2 in FIG. 6A. As illustrated in FIG. 6B, the display apparatus includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layer 175, the insulating layer 174, and the insulating layer 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 6B shows cross sections of a plurality of the inorganic insulating layers 125 and a plurality of the insulating layers 127, the inorganic insulating layers 125 are preferably connected to each other and the insulating layers 127 are preferably connected to each other when the display apparatus is seen from above. In other words, the insulating layer 127 is preferably an insulating layer having an opening portion over a first electrode.

In FIG. 6B, a light-emitting device 130R, a light-emitting device 130G, and a light-emitting device 130B are illustrated as the light-emitting devices 130. The light-emitting device 130R, the light-emitting device 130G, and the light-emitting device 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display apparatus of one embodiment of the present invention can be, for example, a top-emission display apparatus where light is emitted in the direction opposite to a substrate over which light-emitting devices are formed. Note that the display apparatus of one embodiment of the present invention may be of a bottom emission type.

The light-emitting device 130R has the structure described in Embodiment 2. The light-emitting device 130R includes a first electrode 101R (pixel electrode) including a conductive layer 151R and a conductive layer 152R, a first EL layer 104R over the first electrode 101R, an organic compound layer (a second EL layer 105 over the first EL layer 104R), and a second electrode 102 (common electrode) 102 over the second EL layer 105. The second EL layer 105 is preferably positioned closer to the second electrode 102 (common electrode) side than the light-emitting layer is, and is preferably a hole-block layer, an electron-transport layer, an electron-injection layer, or stacked layers thereof. Such a structure can reduce damage to the light-emitting layer or an active layer during a photolithography process, which promises favorable film quality and electrical characteristics. Furthermore, a plurality of layers such as an electron-injection layer may be provided as common layers in contact with the second electrode 102 (common electrode).

The light-emitting device 130G has the structure described in Embodiment 2. The light-emitting device 130G includes a first electrode 101G (pixel electrode) including a conductive layer 151G and a conductive layer 152G, a first EL layer 104G over the first electrode 101G, the second EL layer 105 over the first EL layer 104G, and the second electrode 102 (common electrode) over the second EL layer 105. The second EL layer 105 is preferably a hole-block layer, an electron-transport layer, an electron-injection layer, or stacked layers thereof.

The light-emitting device 130B has the structure described in Embodiment 2. The light-emitting device 130B includes a first electrode 101B (pixel electrode) including a conductive layer 151B and a conductive layer 152B, a first EL layer 104B over the first electrode 101B, the second EL layer 105 over the first EL layer 104B, and the second electrode 102 (common electrode) over the second EL layer 105. The second EL layer 105 is preferably a hole-block layer, an electron-transport layer, an electron-injection layer, or stacked layers thereof.

In the light-emitting device, one of the pixel electrode (first electrode) and the common electrode (second electrode) functions as an anode and the other functions as a cathode. In this embodiment, description is made on the assumption that the pixel electrode functions as the anode and the common electrode functions as the cathode unless otherwise specified.

The first EL layer 104R, the first EL layer 104G, and the first EL layer 104B are island-shaped layers that are independent of each other; alternatively, a first EL layer of the light-emitting devices of one emission color may be independent of a first EL layer of the light-emitting devices of another emission color. Note that it is preferable that the first EL layer 104R, the first EL layer 104G, and the first EL layer 104B not overlap with one another. Providing the island-shaped first EL layer 104 in each of the light-emitting devices 130 can suppress leakage current between the adjacent light-emitting devices 130 even in a high-resolution display apparatus. This can prevent crosstalk, so that a display apparatus with extremely high contrast can be obtained. Specifically, a display apparatus having high current efficiency at low luminance can be obtained.

The island-shaped first EL layer 104 is formed by forming an EL film and processing the EL by a photolithography method.

The first EL layer 104 is preferably provided over the top surface of the first electrode 101 (pixel electrode) of the light-emitting device 130. This can inhibit generation of leakage current and a light-emitting apparatus with high color purity can be easily provided. Covering the side surface of the pixel electrode of the light-emitting device 130 with the first EL layer 104 can inhibit the pixel electrode from being in contact with the second electrode 102; hence, a short circuit of the light-emitting device 130 can be inhibited.

In the display apparatus of one embodiment of the present invention, the first electrode 101 (pixel electrode) of the light-emitting device preferably has a stacked-layer structure. For example, in the example illustrated in FIG. 6B, the first electrode 101 of the light-emitting device 130 has a stacked-layer structure of the conductive layer 151 provided on the insulating layer 171 side and the conductive layer 152 provided on the organic compound layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 may have a stack-layer structure of a plurality of layers containing different materials, and the conductive layer 152 may have a stacked-layer structure of a plurality of layers containing different materials. In that case, the conductive layer 151 may include a layer formed using a material that can be used for the conductive layer 152, such as a conductive oxide, and the conductive layer 152 may include a layer formed using a material that can be used for the conductive layer 151, such as a metal material. In the case where the conductive layer 151 has a stack-layer structure of two or more layers, for example, a layer in contact with the conductive layer 152 can be a layer formed using a material that can be used for the conductive layer 152.

Note that the conductive layer 151 may have a tapered end portion. Specifically, the conductive layer 151 preferably has a tapered end portion with a taper angle of less than 90°. In that case, the conductive layer 152 provided along the side surface of the conductive layer 151 also has a tapered shape. When the side surface of the conductive layer 152 has a tapered shape, coverage with the first EL layer 104 provided along the side surface of the conductive layer 152 can be improved. Note that the end portion of the conductive layer 151 does not necessarily have a tapered shape and may be substantially perpendicular to the substrate surface. In that case, the distance between adjacent EL layers can be short, and thus a light-emitting apparatus having a high aperture ratio can be provided.

Since the light-emitting device 130 has the structure described in Embodiment 2, the light-emitting apparatus of one embodiment of the present invention can have high reliability. Furthermore, since the light-emitting apparatus of one embodiment of the present invention includes the steps described in Embodiment 1 in the fabrication process, the light-emitting apparatus whose generation of defects is inhibited, fabrication can be performed with high yield, and cost is relatively inexpensive can be provided.

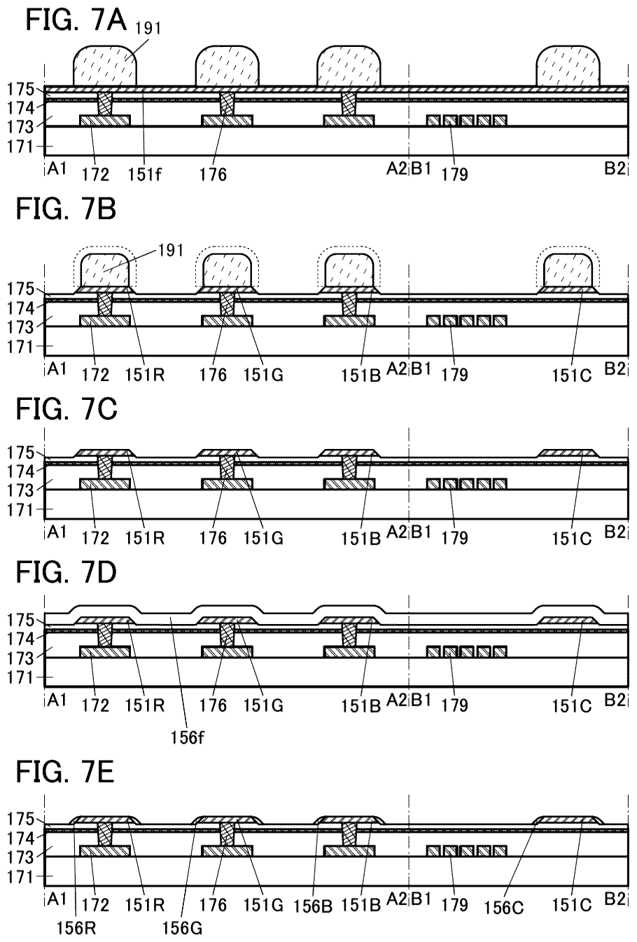

Next, a method for fabricating the display apparatus having the structure illustrated in FIG. 6A is described with reference to FIG. 7 to FIG. 12.

### [Fabrication Method Example]

Thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Thin films included in the display apparatus (e.g., insulating films, semiconductor films, and conductive films) can also be formed by a wet film formation process such as spin coating, dipping, spray coating, ink-jetting, dispensing, screen printing, offset printing, doctor blade coating, slit coating, roll coating, curtain coating, or knife coating.

Thin films included in the display apparatus can be processed by a photolithography method, for example.

As light used for exposure in the photolithography method, for example, an i-line (wavelength: 365 nm), a g-line (wavelength: 436 nm), an h-line (wavelength: 405 nm), or light in which these lines are mixed can be used. Alternatively, ultraviolet rays, KrF laser light, ArF laser light, or the like can be used. Exposure may be performed by a liquid immersion exposure technique. As the light used for exposure, extreme ultraviolet (EUV) light or X-rays may also be used. Furthermore, instead of the light used for exposure, an electron beam can be used.

For etching of thin films, a dry etching method, a wet etching method, a sandblast method, or the like can be used.

First, as illustrated in FIG. 7A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramics substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 7A, openings reaching the conductive layer 172 are formed in the insulating layer 175, the insulating layer 174, and the insulating layer 173. Then, the plugs 176 are formed to fill the openings.

Next, as illustrated in FIG. 7A, a conductive film 151f to be the conductive layer 151R, the conductive layer 151G, the conductive layer 151B, and the conductive layer 151C is formed over the plugs 176 and the insulating layer 175. A metal material can be used for the conductive film 151f, for example.

Then, a resist mask 191 is formed over the conductive film 151f as illustrated in FIG. 7A. The resist mask 191 can be formed by application of a photosensitive material (photoresist), light exposure, and development.

Subsequently, as illustrated in FIG. 7B, the conductive film 151f in a region not overlapping with the resist mask 191 is removed, for example. In this manner, the conductive layer 151 is formed.

Next, the resist mask 191 is removed as illustrated in FIG. 7C. The resist mask 191 can be removed by ashing using oxygen plasma, for example.

Then, as illustrated in FIG. 7D, an insulating film 156f to be an insulating layer 156R, an insulating layer 156G, an insulating layer 156B, and an insulating layer 156C is formed over the conductive layer 151R, the conductive layer 151G, the conductive layer 151B, the conductive layer 151C, and the insulating layer 175.

As the insulating film 156f, an inorganic insulating film such as an oxide insulating film, a nitride insulating film, an oxynitride insulating film, or a nitride oxide insulating film, e.g., silicon oxynitride, can be used.

Subsequently, as illustrated in FIG. 7E, the insulating film 156f is processed to form the insulating layer 156R, the insulating layer 156G, the insulating layer 156B, and the insulating layer 156C.

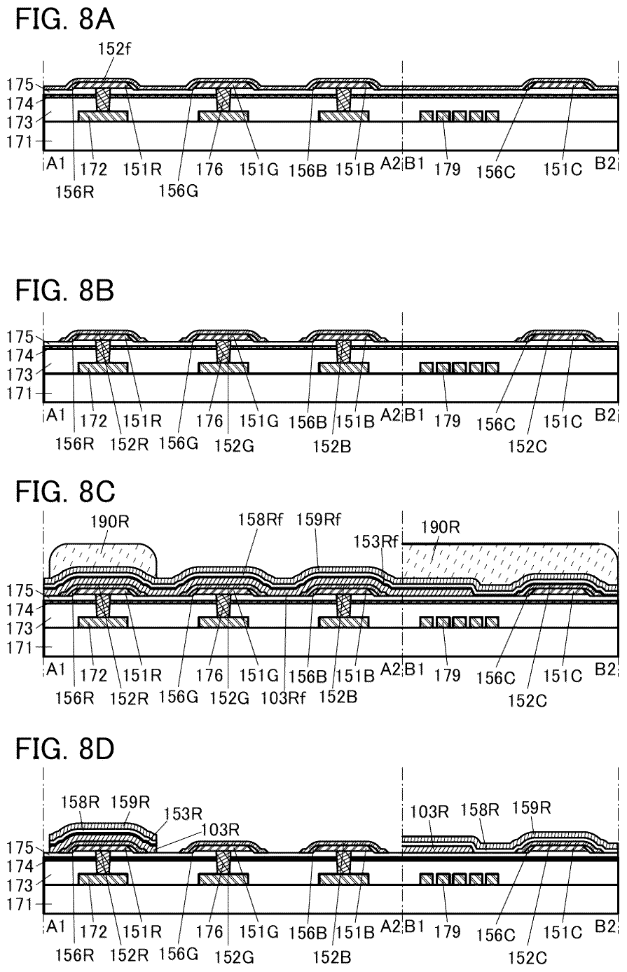

Next, as illustrated in FIG. 8A, a conductive film 152f is formed over the conductive layer 151R, the conductive layer 151G, the conductive layer 151B, the conductive layer 151C, the insulating layer 156R, the insulating layer 156G, the insulating layer 156B, the insulating layer 156C, and the insulating layer 175.

A conductive oxide can be used for the conductive film 152f, for example. The conductive film 152f may have a stacked-layer structure.

Then, as illustrated in FIG. 8B, the conductive film 152f is processed to form the conductive layer 152R, the conductive layer 152G, the conductive layer 152B, and the conductive layer 152C.

Next, as illustrated in FIG. 8C, an organic compound film 103Rf is formed over the conductive layer 152R, the conductive layer 152G, the conductive layer 152B, and the insulating layer 175. As illustrated in FIG. 8C, the organic compound film 103Rf is not formed over the conductive layer 152C.

Then, as illustrated in FIG. 8C, a structure body layer 153Rf, a protective film 158Rf, and a mask film 159Rf are formed.

The protective film 158Rf provided over the organic compound film 103Rf can reduce damage to the organic compound film 103Rf in the fabrication process of the display apparatus, increasing the reliability of the light-emitting device. The formation of the structure body layer 153Rf can inhibit the protective film 158Rf separating (peeling) from the organic compound film 103Rf or an organic compound layer 103R during the manufacturing process.

As the protective film 158Rf, a film that is highly resistant to the process conditions for the organic compound film 103Rf, specifically, a film having high etching selectivity with respect to the organic compound film 103Rf is used. As the mask film 159Rf, a film having high etching selectivity with respect to the protective film 158Rf is used.

The structure body layer 153Rf, the protective film 158Rf, and the mask film 159Rf are formed at a temperature lower than the upper temperature limit of the organic compound film 103Rf. The typical substrate temperatures information of the protective film 158Rf and the mask film 159Rf are each higher than or equal to 100 °C and lower than or equal to 200 °C, preferably higher than or equal to 100 °C and lower than or equal to 150 °C, further preferably higher than or equal to 100 °C and lower than or equal to 120 °C. Since the structure body layer 153Rf is an organic compound or an organometallic complex as described in Embodiment 1, the structure body layer 153Rf can be formed under conditions similar to those for the organic compound film.

As the structure body layer 153Rf, the protective film 158Rf and the mask film 159Rf, films that can be removed by a wet etching method or a dry etching method are preferably used.

Note that the protective film 158Rf, which is formed closer to the organic compound film 103Rf, is preferably formed by a formation method that causes less damage to the organic compound film 103Rf than a formation method of the mask film 159Rf. For example, the protective film 158Rf is preferably formed by an ALD method (Atomic Layer Deposition method) or a vacuum evaporation method rather than a sputtering method.

As each of the protective film 158Rf and the mask film 159Rf, one or more kinds of a metal film, an alloy film, a metal oxide film, a semiconductor film, an organic insulating film, and an inorganic insulating film, for example, can be used.

For each of the protective film 158Rf and the mask film 159Rf, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used, for example. It is particularly preferable to use a low-melting-point material such as aluminum or silver. It is preferable to use a metal material that can block ultraviolet rays for one or both of the protective film 158Rf and the mask film 159Rf, in which case the organic compound film 103Rf can be inhibited from being irradiated with ultraviolet rays in patterning light exposure, and deterioration of the organic compound film 103Rf can be inhibited.

The protective film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The protective film 158Rf and the mask film 159Rf are preferably formed using a semiconductor material such as silicon or germanium for excellent compatibility with a semiconductor manufacturing process. Alternatively, a compound containing the above semiconductor material can be used.

As each of the protective film 158Rf and the mask film 159Rf, any of a variety of inorganic insulating films can be used. In particular, an oxide insulating film is preferable because its adhesion to the organic compound film 103Rf is higher than that of a nitride insulating film. A nitride insulating film, which is dense and has a high barrier property, is preferable. As the nitride insulating film, it is particularly preferable to use a silicon nitride film.

Subsequently, a resist mask 190R is formed as illustrated in FIG. 8C. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged in the fabrication process of the display apparatus.

Next, as illustrated in FIG. 8D, part of the mask film 159Rf is removed using the resist mask 190R, so that a mask layer 159R is formed. The mask layer 159R remains over the conductive layer 152R and the conductive layer 152C. After that, the resist mask 190R is removed. Then, part of the protective film 158Rf is removed using the mask layer 159R as a mask (also referred to as a hard mask), so that a protective layer 158R is formed.

The use of a wet etching method can reduce damage to the organic compound film 103Rf in processing of the protective film 158Rf and the mask film 159Rf, as compared to the case of using a dry etching method. In the case of using a wet etching method, it is preferable to use an alkaline aqueous solution such as a developer or a tetramethylammonium hydroxide (TMAH) aqueous solution, or an acid aqueous solution such as dilute hydrofluoric acid, oxalic acid, phosphoric acid, acetic acid, nitric acid, or a chemical solution containing a mixed solution of any of these acids, for example.

In the case of using a dry etching method to process the protective film 158Rf, deterioration of the organic compound film 103Rf can be inhibited by not using a gas containing oxygen as the etching gas.

The resist mask 190R can be removed by a method similar to that for the resist mask 191.

Next, as illustrated in FIG. 8D, the structure body layer 153Rf and the organic compound film 103Rf are processed to form a structure body layer 153R and the organic compound layer 103R, respectively. For example, parts of the structure body layer 153Rf and the organic compound film 103Rf are removed using the mask layer 159R and the protective layer 158R as hard masks, whereby the structure body layer 153R and the organic compound layer 103R are formed.

Accordingly, as illustrated in FIG. 8D, the stacked-layer structure of the organic compound layer 103R, the structure body layer 153R, the protective layer 158R, and the mask layer 159R remains over the conductive layer 152R. The conductive layer 152G and the conductive layer 152B are exposed.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

Alternatively, a gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated during the etching can be inhibited.

In the case of using a dry etching method, it is preferable to use a gas containing at least one kind of H₂, CF₄, C₄F₈, SF₆, CHF₃, Cl₂, H₂O, BCl₃, and a Group 18 element such as He or Ar as the etching gas, for example. Alternatively, a gas containing oxygen and at least one kind of the above is preferably used as the etching gas. Alternatively, an oxygen gas may be used as the etching gas.

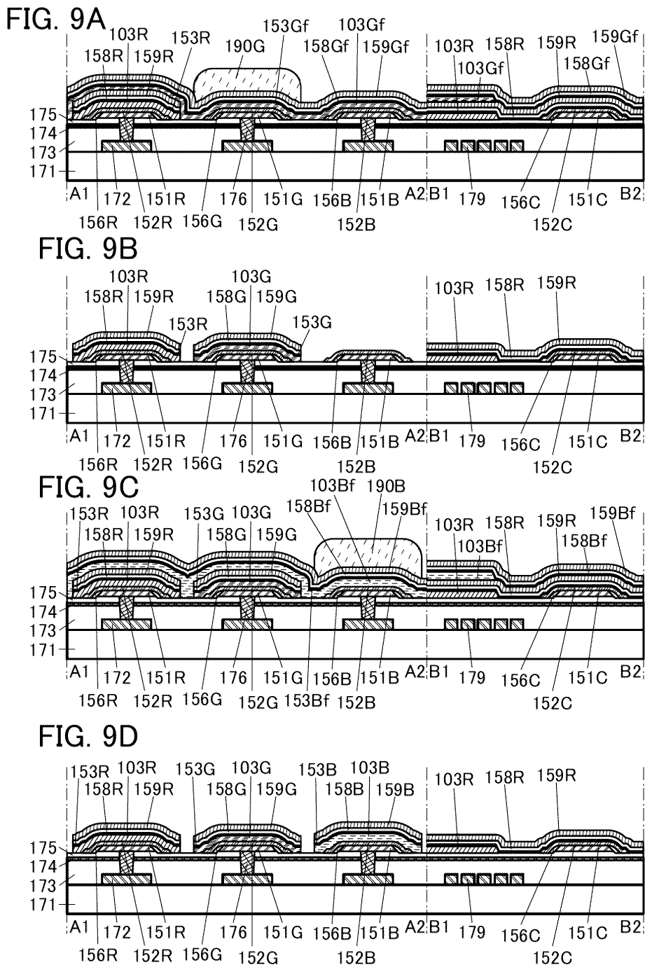

Then, as illustrated in FIG. 9A, an organic compound film 103Gf to be an organic compound layer 103G is formed.

The organic compound film 103Gf can be formed by a method similar to the method that can be used for forming the organic compound film 103Rf.

Subsequently, as illustrated in FIG. 9A, a structure body layer 153Gf, a protective film 158Gf, and a mask film 159Gf are formed in this order. After that, a resist mask 190G is formed. The materials and the formation methods of the structure body layer 153Gf, the protective film 158Gf, and the mask film 159Gf are similar to conditions applicable to the structure body layer 153Rf, the protective film 158Rf, and the mask film 159Rf. The material and the formation method of the resist mask 190G are similar to conditions applicable to the resist mask 190R.

The resist mask 190G is preferably provided at a position overlapping with the conductive layer 152G.

Subsequently, as illustrated in FIG. 9B, part of the mask film 159Gf is removed using the resist mask 190G, so that a mask layer 159G is formed. The mask layer 159G remains over the conductive layer 152G. After that, the resist mask 190G is removed. Then, part of the protective film 158Gf is removed using the mask layer 159G as a mask, so that a protective layer 158G is formed. Next, the structure body layer 153Gf and the organic compound film 103Gf are processed to form a structure body layer 153G and the organic compound layer 103G, respectively. Accordingly, as illustrated in FIG. 9B, the stacked-layer structure of the organic compound layer 103G, the structure body layer 153G, the protective layer 158G, and the mask layer 159G remains over the conductive layer 152G. The mask layer 159R and the conductive layer 152B are exposed.

Then, an organic compound film 103Bf is formed as illustrated in FIG. 9C.

The organic compound film 103Bf can be formed by a method similar to the method that can be used for forming the organic compound film 103Rf.

Subsequently, a structure body layer 153Bf, a protective film 158Bf, and a mask film 159Bf are formed in this order as illustrated in FIG. 9C. After that, a resist mask 190B is formed. The materials and the formation methods of the structure body layer 153Bf, the protective film 158Bf, and the mask film 159Bf are similar to conditions applicable to the structure body layer 153Rf, the protective film 158Rf, and the mask film 159Rf. The material and the formation method of the resist mask 190B are similar to conditions applicable to the resist mask 190R.

The resist mask 190B is provided at a position overlapping with the conductive layer 152B.

Subsequently, as illustrated in FIG. 9D, part of the mask film 159Bf is removed using the resist mask 190B, so that a mask layer 159B is formed. The mask layer 159B preferably remains over the conductive layer 152B. After that, the resist mask 190B is removed. Then, part of the protective film 158Bf is removed using the mask layer 159B as a mask, so that a protective layer 158B is formed. Next, the structure body layer 153Bf and the organic compound film 103Bf are processed to form an organic compound layer 103B. For example, parts of the structure body layer 153Bf and the organic compound film 103Bf are removed using the mask layer 159B and the protective layer 158B as hard masks, whereby a structure body layer 153B and the organic compound layer 103B are formed.

Accordingly, the stacked-layer structure of the organic compound layer 103B, the structure body layer 153B, the protective layer 158B, and the mask layer 159B remains over the conductive layer 152B as illustrated in FIG. 9D. The mask layer 159R and the mask layer 159G are exposed.

Note that the side surfaces of the organic compound layer 103R, the organic compound layer 103G, and the organic compound layer 103B are preferably perpendicular or substantially perpendicular to their formation surfaces. For example, the angle between the formation surfaces and these side surfaces is preferably greater than or equal to 60° and less than or equal to 90°.

The distance between two adjacent layers among the organic compound layer 103R, the organic compound layer 103G, and the organic compound layer 103B, which are formed by a photolithography method as described above, can be reduced to less than or equal to 8 μm, less than or equal to 5 μm, less than or equal to 3 μm, less than or equal to 2 μm, or less than or equal to 1 μm. Here, the distance can be specified, for example, by the distance between facing end portions of two adjacent layers among the organic compound layer 103R, the organic compound layer 103G, and the organic compound layer 103B. Reducing the distance between the island-shaped organic compound layers makes it possible to provide a display apparatus having high resolution and a high aperture ratio. In addition, the distance between the first electrodes of adjacent light-emitting devices can also be reduced to, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 m and less than or equal to 5 μm.

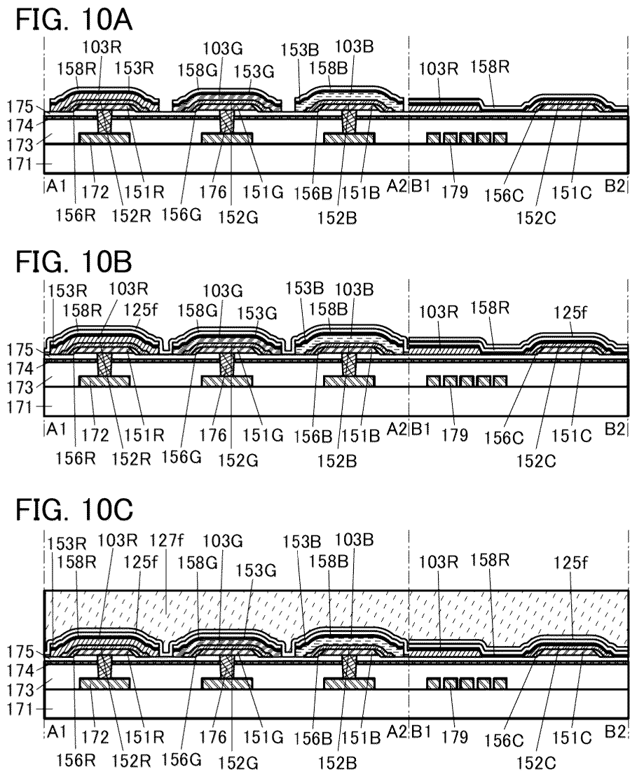

Next, the mask layer 159R, the mask layer 159G, and the mask layer 159B are preferably removed as illustrated in FIG. 10A.

The step of removing the mask layers can be performed by a method similar to that for the step of processing the mask films. Specifically, by using a wet etching method, damage caused to the organic compound layer 103 at the time of removing the mask layers can be reduced as compared to the case of using a dry etching method.

The mask layers may be removed by being dissolved in a polar solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50 °C and lower than or equal to 200 °C, preferably higher than or equal to 60 °C and lower than or equal to 150 °C, and further preferably higher than or equal to 70 °C and lower than or equal to 120 °C. A reduced-pressure atmosphere is preferable, in which case drying at a lower temperature is possible.

Next, an inorganic insulating film 125f is formed as illustrated in FIG. 10B.

Then, as illustrated in FIG. 10C, an insulating film 127f to be the insulating layer 127 is formed over the inorganic insulating film 125f.

The substrate temperature at the time of forming the inorganic insulating film 125f and the insulating film 127f is preferably higher than or equal to 60 °C, higher than or equal to 80 °C, higher than or equal to 100 °C, or higher than or equal to 120 °C and lower than or equal to 200 °C, lower than or equal to 180 °C, lower than or equal to 160 °C, lower than or equal to 150 °C, or lower than or equal to 140 °C.

As the inorganic insulating film 125f, an insulating film having a thickness of 3 nm or more, 5 nm or more, or 10 nm or more and 200 nm or less, 150 nm or less, 100 nm or less, or 50 nm or less is preferably formed at a substrate temperature in the above-described range.

The inorganic insulating film 125f is preferably formed by an ALD method, for example. An ALD method is preferably used, in which case film formation damage can be reduced and a film with good coverage can be formed. As the inorganic insulating film 125f, an aluminum oxide film is preferably formed by an ALD method, for example.

The insulating film 127f is preferably formed by the aforementioned wet film formation process. For example, the insulating film 127f is preferably formed by spin coating using a photosensitive material, and specifically preferably formed using a photosensitive resin composition containing an acrylic resin.

Then, light exposure is performed to expose part of the insulating film 127f to visible light or ultraviolet rays. The insulating layer 127 is formed in regions that are sandwiched between any two of the conductive layer 152R, the conductive layer 152G, and the conductive layer 152B and around the conductive layer 152C.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

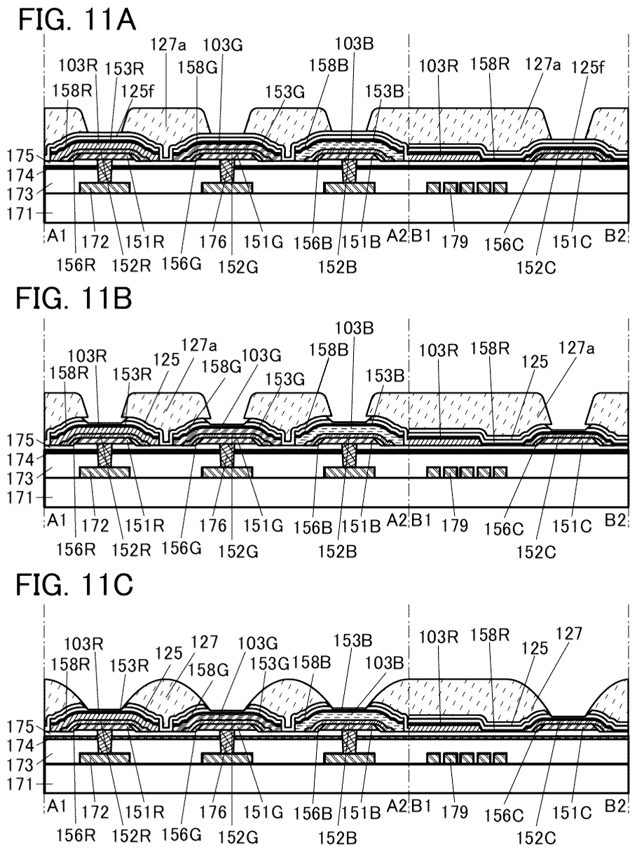

Next, the region of the insulating film 127f exposed to light is removed by development as illustrated in FIG. 11A, so that an insulating layer 127a is formed.

Next, as illustrated in FIG. 11B, etching treatment is performed with the insulating layer 127a as a mask to remove part of the inorganic insulating film 125f and reduce the thickness of part of the protective layer 158R, the protective layer 158G, and the protective layer 158B. Thus, the inorganic insulating layer 125 is formed under the insulating layer 127a. Moreover, the surfaces of the thin portions of the protective layer 158R, the protective layer 158G, and the protective layer 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the protective layer 158R, the protective layer 158G, and the protective layer 158B, in which case the first etching treatment can be performed concurrently.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the protective layer 158R, the protective layer 158G, and the protective layer 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the organic compound layer 103R, the organic compound layer 103G, and the organic compound layer 103B, as compared to the case of using a dry etching method. Wet etching can be performed using an alkaline solution, for example. For instance, TMAH, which is an alkaline solution, can be used for the wet etching of an aluminum oxide film. Alternatively, an acid solution containing fluoride can also be used. In this case, puddle wet etching can be performed. Note that the inorganic insulating film 125f is preferably formed using a material similar to that of the protective layer 158R, the protective layer 158G, and the protective layer 158B, in which case the above etching treatment can be performed concurrently.

The protective layer 158R, the protective layer 158G, and the protective layer 158B are not completely removed by the first etching treatment, and the etching treatment is stopped when the thickness thereof is reduced. The corresponding protective layer 158R, protective layer 158G, and protective layer 158B remain over the organic compound layer 103R, the organic compound layer 103G, and the organic compound layer 103B in this manner, whereby the organic compound layer 103R, the organic compound layer 103G, and the organic compound layer 103B can be prevented from being damaged by treatment in a later step.

Although peeling is likely to occur between the organic compound layer 103 and the protective layer 158 after the first etching treatment, in the method for fabricating the organic semiconductor device of one embodiment of the present invention, providing the structure body layer 153 between the protective layer 158 and the organic compound layer 103 can inhibit occurrence of the peeling. As a result, the organic semiconductor apparatus (individually, a display apparatus) can be fabricated with high yield and the organic semiconductor apparatus that is inexpensive can be easily provided.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the protective layer 158R, the protective layer 158G, and the protective layer 158B, diffusion of oxygen into the organic compound layer 103R, the organic compound layer 103G, and the organic compound layer 103B can be suppressed.

Then, heat treatment (also referred to as post-baking) is performed. The heat treatment can change the insulating layer 127a into the insulating layer 127 having a tapered side surface (FIG. 11C). The heat treatment is conducted at a temperature lower than the upper temperature limit of the organic compound layer. The heat treatment can be performed at a substrate temperature higher than or equal to 50 °C and lower than or equal to 200 °C, preferably higher than or equal to 60 °C and lower than or equal to 150 °C, and further preferably higher than or equal to 70 °C and lower than or equal to 130 °C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the protective layer 158R, the protective layer 158G, and the protective layer 158B are not completely removed by the first etching treatment and the thinned protective layer 158R, protective layer 158G, and protective layer 158B are left, the organic compound layer 103R, the organic compound layer 103G, and the organic compound layer 103B can be prevented from being damaged and deteriorating in the heat treatment. This increases the reliability of the light-emitting device.

Next, as illustrated in FIG. 11A, etching treatment is performed with the insulating layer 127 as a mask to remove part of the structure body layer 153R, the protective layer 158R, the structure body layer 153G, the protective layer 158G, the structure body layer 153B, and the protective layer 158B. Thus, openings are formed in the structure body layer 153R, the protective layer 158R, the structure body layer 153G, the protective layer 158G, the structure body layer 153B, and the protective layer 158B, and the top surfaces of the organic compound layer 103R, the organic compound layer 103G, the organic compound layer 103B, and the conductive layer 152C are exposed. Note that this etching treatment may be hereinafter referred to as second etching treatment.

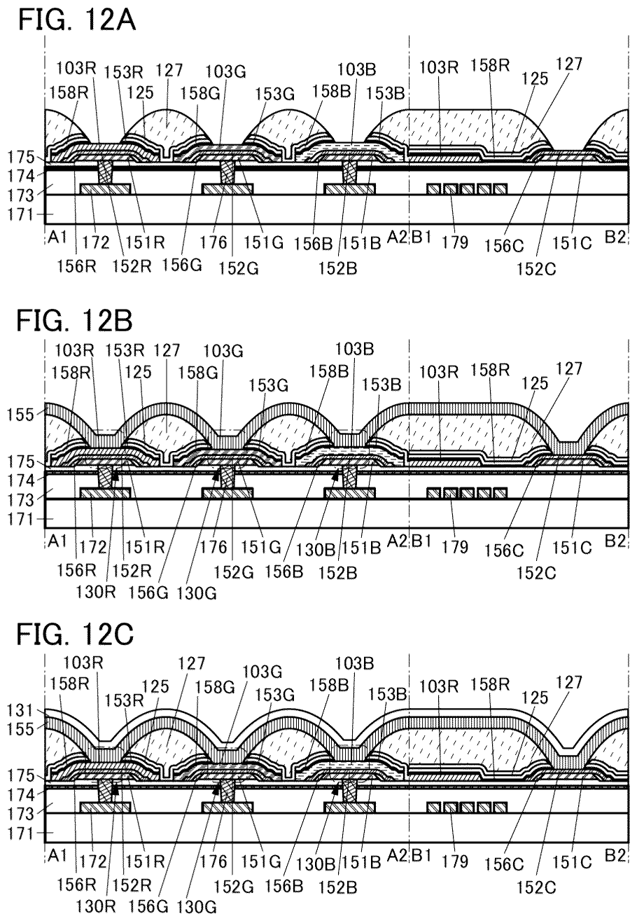

An end portion of the inorganic insulating layer 125 is covered with the insulating layer 127. FIG. 12A illustrates an example in which part of an end portion of the protective layer 158G (specifically, a tapered portion formed by the first etching treatment) is covered with the insulating layer 127 and a tapered portion formed by the second etching treatment is exposed.

The second etching treatment is performed by wet etching. The use of a wet etching method can reduce damage to the organic compound layer 103R, the organic compound layer 103G, and the organic compound layer 103B, as compared to the case of using a dry etching method. Wet etching can be performed using an alkaline solution or an acidic solution, for example. An aqueous solution is preferable in order that the organic compound layer 103 is not dissolved.

Next, as illustrated in FIG. 12B, a common electrode 155 is formed over the organic compound layer 103R, the organic compound layer 103G, the organic compound layer 103B, the conductive layer 152C, and the insulating layer 127. The common electrode 155 can be formed by a sputtering method, a vacuum evaporation method, or the like. In this case, a stacked-layer structure of the first EL layer 104 and the second EL layer 105 may be formed as the organic compound layer 103 as illustrated in FIG. 6B, and the common electrode 155 may be formed thereover.

Next, as illustrated in FIG. 12C, the protective layer 131 is formed over the common electrode 155. The protective layer 131 can be formed by a vacuum evaporation method, a sputtering method, a CVD method, an ALD method, or the like.

Then, the substrate 120 is bonded over the protective layer 131 using the resin layer 122, so that the display apparatus can be fabricated. In the method for fabricating the display apparatus of one embodiment of the present invention, the insulating layer 156 is provided to include a region overlapping with the side surface of the conductive layer 151 and the conductive layer 152 is formed to cover the conductive layer 151 and the insulating layer 156 as described above. This can increase the yield of the display apparatus and inhibit generation of defects.

As described above, in the method for fabricating the display apparatus in one embodiment of the present invention, the island-shaped organic compound layer 103R, the island-shaped organic compound layer 103G, and the island-shaped organic compound layer 103B are formed not by using a fine metal mask but by processing a film formed on the entire surface; thus, the island-shaped layers can be formed to have a uniform thickness. Consequently, a high-resolution display apparatus or a display apparatus with a high aperture ratio can be obtained. Furthermore, even when the resolution or the aperture ratio is high and the distance between the subpixels is extremely short, the organic compound layer 103R, the organic compound layer 103G, and the organic compound layer 103B can be inhibited from being in contact with each other in the adjacent subpixels. As a result, generation of leakage current between the subpixels can be inhibited. This can prevent crosstalk, so that a display apparatus with extremely high contrast can be obtained. Moreover, even a display apparatus that includes tandem light-emitting devices fabricated by a photolithography method can be provided as a display apparatus having favorable characteristics.

The structure of this embodiment can be used in combination with any of the other structures as appropriate.

### Embodiment 4

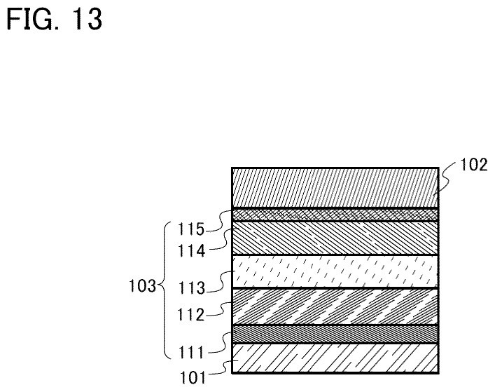

In this embodiment, a structure of an organic EL device, which is an organic semiconductor device including an EL layer as an organic semiconductor layer, is described with reference to FIG. 13. The organic EL device is an organic semiconductor device that includes an EL layer including a light-emitting layer between the first electrode 101 and the second electrode 102.

Note that one of the first electrode 101 and the second electrode 102 functions as an anode, and the other functions as a cathode. A case where the first electrode 101 is an anode is illustrated as an example in FIG. 13.

The anode is preferably formed using a metal, an alloy, a conductive compound, or a mixture thereof each having a high work function (specifically, higher than or equal to 4.0 eV), for example. Specific examples include indium oxide-tin oxide (ITO: Indium Tin Oxide), indium oxide-tin oxide containing silicon or silicon oxide (ITSO: Indium Tin Silicon Oxide), indium oxide-zinc oxide, and indium oxide containing tungsten oxide and zinc oxide (IWZO). Films of such conductive metal oxides are usually formed by a sputtering method, but may be fabricated by a sol-gel method or the like. An example of the fabrication method is a method in which indium oxide-zinc oxide is formed by a sputtering method using a target in which 1 to 20 wt % zinc oxide is added to indium oxide. Furthermore, indium oxide containing tungsten oxide and zinc oxide (IWZO) can be formed by a sputtering method using a target in which 0.5 to 5 wt % tungsten oxide and 0.1 to 1 wt % zinc oxide are added to indium oxide. Other examples of materials used for the anode include gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), and nitride of a metal material (e.g., titanium nitride). The anode may be a stack of layers of any of these materials. For example, a film in which Al, Ti, and ITSO are stacked in this order over Ti is preferable because the film has high efficiency owing to high reflectivity and enables a high resolution of several thousand ppi. Alternatively, graphene can also be used as a material for the anode. Note that when a composite material described later, which can be contained in the hole-injection layer 111, is used for a layer (typically, a hole-injection layer) that is in contact with the anode, an electrode material can be selected regardless of its work function.

The hole-injection layer 111 is provided in contact with the anode and has a function of facilitating injection of holes into the organic compound layer 103. The hole-injection layer 111 can be formed using phthalocyanine (abbreviation: H₂Pc) or a phthalocyanine-based compound or complex such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N-phenylamino]phenyl}-N-phenylamino)biphenyl (abbreviation: DNTPD), a high molecular compound such as poly(3,4-ethylenedioxythiophene)/(polystyrenesulfonic acid) (abbreviation: PEDOT/PSS), or the like.

The hole-injection layer 111 may be formed using a substance having an electron-acceptor property. As the substance having an electron-accepting property, an organic compound having an electron-withdrawing group (a halogen group, a cyano group, or the like) can be used, and examples thereof include 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an electron-accepting property, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing the above substance having an electron-accepting property and the organic compound having a hole-transport property.

As the organic compound having a hole-transport property used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property used in the composite material is preferably an organic compound having a hole mobility of 1×10⁻⁶ cm²/Vs or higher. The organic compound having a hole-transport property used in the composite material is preferably a compound having a condensed aromatic hydrocarbon ring or a π-electron rich heteroaromatic ring. As the condensed aromatic hydrocarbon ring, an anthracene ring, a naphthalene ring, or the like is preferable. As the 7t-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably a substance having an N,N-bis(4-biphenyl)amino group to enable fabricating a light-emitting device having a long lifetime.

Specific examples of the above-described organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNPNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAβPNB-03), 4,4′-diphenyl-4″-(6;2′-binaphthyl-2-yl)triphenylamine (abbreviation: BBA(PN2)B), 4,4′-diphenyl-4″-(7;2′-binaphthyl-2-yl)triphenylamine (abbreviation: BBA(PN2)B-03), 4,4′-diphenyl-4″-(4;2′-binaphthyl-1-yl)triphenylamine (abbreviation: BBAPNaNB), 4,4′-diphenyl-4″-(5;2′-binaphthyl-1-yl)triphenylamine (abbreviation: BBAPNaNB-02), 4-(4-biphenylyl)-4′-(2-naphthyl)-4″-phenyltriphenylamine (abbreviation: TPBiAPNB), 4-(3-biphenylyl)-4′-[4-(2-naphthyl)phenyl]-4″-phenyltriphenylamine (abbreviation: mTPBiAPNBi), 4-(4-biphenylyl)-4′-[4-(2-naphthyl)phenyl]-4″-phenyltriphenylamine (abbreviation: TPBiA[3NBi), 4-phenyl-4′-(1-naphthyl)triphenylamine (abbreviation: aNBA1BP), 4,4′-bis(1-naphthyl)triphenylamine (abbreviation: aNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBi[3NB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

For another aromatic amine compound as the material having a hole-transport property, N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), or the like can also be used.

The formation of the hole-injection layer 111 can improve the hole-injection property, whereby a light-emitting device having a low driving voltage can be obtained.

Among substances having an electron-accepting property, an organic compound having an electron-accepting property is easy to use because it is easily formed as a film by vapor deposition.

The hole-transport layer 112 is formed to contain an organic compound having a hole-transport property. The organic compound having a hole-transport property preferably has a hole mobility of 1×10⁻⁶ cm²/Vs or higher.

Examples of the above-described material having a hole-transport property include a compound having an aromatic amine skeleton, such as 4,4′-bis[N-(1-naphthyl)-N-phenylamino]biphenyl (abbreviation: NPB), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisPNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, or 9-[4-(9-phenyl-9H-carbazol-3-yl)phenyl]phenanthrene (abbreviation: PCPPn); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. Note that any of the substances given as examples of the material having a hole-transport property used for the composite material for the hole-injection layer 111 can also be suitably used as the material contained in the hole-transport layer 112.

The light-emitting layer 113 is a layer containing a light-emitting substance and preferably contains a light-emitting substance and a host material. Note that the light-emitting layer may additionally contain other materials. Alternatively, the light-emitting layer may be a stack of two layers with different compositions.

The light-emitting substance may be a fluorescent substance, a phosphorescent substance, a substance exhibiting thermally activated delayed fluorescence (TADF), or another light-emitting substance.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N,N-triphenyl-1,4-phenylenediamine](abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N,N,N′,N′,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(biphenyl-2-yl)-2-anthryl]-N,N,N-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,l0FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping property, high emission efficiency, or high reliability. Condensed aromatic diamine compounds typified by pyrenediamine compounds such as 1,6FLPAPrn, 1,6mMemFLPAPrn, and 1,6BnfAPrn-03 are particularly preferable because of their high hole-trapping property, high emission efficiency, or high reliability.

A condensed heteroaromatic compound containing nitrogen and boron, especially a compound having a diaza-boranaphtho-anthracene skeleton, exhibits a narrow emission spectrum, emits blue light with high color purity, and can thus be suitably used. Examples of the compound include 5,9-diphenyl-5,9-diaza-13b-boranaphtho[3,2,1-de]anthracene (abbreviation: DABNA1), 9-(diphenyl-3-yl)-N,N,5,11-tetraphenyl-5,9-dihydro-5,9-diaza-13b-boranaphtho[3,2,1-de]anthracen-3-amine (abbreviation: DABNA2), 2,12-di(tert-butyl)-5,9-di(4-tert-butylphenyl)-N,N-diphenyl-5H,9H-[1,4]benzazaborino[2,3,4-k/]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-kl]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′: 4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl)indolo[3,2,1-de]indolo[3′,2′,1′: 8,1][1,4]benzazaborino[2,3,4-kl]phenazaborine (abbreviation: BBCz-Y), or the like can be suitably used.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-xN2]phenyl-xC}iridium(III) (abbreviation: [Ir(mpptz-dmp)3]) or tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-TH-1,2,4-triazolato]iridium(III) (abbreviation: [Ir(Mptz1-mp)₃]) or tris(1-methyl-5-phenyl-3-propyl-TH-1,2,4-triazolato)iridium(III) (abbreviation: [Ir(Prptzl-Me)₃]); an organometallic iridium complex having an imidazole skeleton, such as fac-tris[1-(2,6-diisopropylphenyl)-2-phenyl-TH-imidazole]iridium(III) (abbreviation: [Ir(iPrpim)3]), tris[3-(2,6-dimethylphenyl)-7-methylimidazo[1,2-f]phenanthridinato]iridium(III) (abbreviation: [Ir(dmpimpt-Me)₃]), or tris(2-[1-{2,6-bis(1-methylethyl)phenyl}-1H-imidazol-2-yl-xN3}-4-cyanophenyl-xC) (abbreviation: CNImIr); an organometallic complex having a benzimidazolidene skeleton, such as tris[(6-tert-butyl-3-phenyl-2H-imidazo[4,5-b]pyrazin-1-yl-xC2)phenyl-xC]iridium(III) (abbreviation: [Ir(cb)₃]); and an organometallic iridium complex in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²′]iridium(III) picolinate (abbreviation: FIrpic), bis{2-[3′,5′-bis(trifluoromethyl)phenyl]pyridinato-N,C²′}iridium(III) picolinate (abbreviation: [Ir(CF3ppy)2(pic)]), or bis[2-(4′,6′-difluorophenyl)pyridinato-N,C²′]iridium(III) acetylacetonate (abbreviation: FIracac). These compounds exhibit blue phosphorescent light and have an emission peak in the wavelength range of 450 nm to 520 nm.

Other examples include an organometallic iridium complex having a pyrimidine skeleton, such as tris(4-methyl-6-phenylpyrimidinato)iridium(III) (abbreviation: [Ir(mppm)3]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)2(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)2(acac)]); an organometallic iridium complex having a pyridine skeleton, such as tris(2-phenylpyridinato-N,C2′)iridium(III) (abbreviation: [Ir(ppy)3]), bis(2-phenylpyridinato-N,C2′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C2′)iridium(III) (abbreviation: [Ir(pq)₃]), bis(2-phenylquinolinato-N,C2′)iridium(III) acetylacetonate (abbreviation: [Ir(pq)2(acac)]), [2-d3-methyl-8-(2-pyridinyl-xN)benzofuro[2,3-b]pyridine-xC]bis[2-(5-d₃-methyl-2-pyridinyl-xN2)phenyl-xC]iridium(III) (abbreviation: [Ir(5mppy-d₃)2(mbfpypy-d₃)]), [2-d₃-methyl-(2-pyridinyl-xN)benzofuro[2,3-b]pyridine-xC]bis[2-(2-pyridinyl-KN)phenyl-xC]iridium(III) (abbreviation: [Ir(ppy)₂(mbfpypy-d₃)]), [2-(4-d3-methyl-5-phenyl-2-pyridinyl-xN2)phenyl-xC]bis[2-(5-d3-methyl-2-pyridinyl-xN2)phenyl-xC]iridium(III) (abbreviation: [Ir(5mppy-d₃)2(mdppy-d₃)]), [2-methyl-(2-pyridinyl-1N)benzofuro[2,3-b]pyridine-xC]bis[2-(2-pyridinyl-xN)phenyl-xC]iridium(III) (abbreviation: [Ir(ppy)₂(mbfpypy)]), or [2-(4-methyl-5-phenyl-2-pyridinyl-xN)phenyl-xC]bis[2-(2-pyridinyl-1N)phenyl-xC]iridium (abbreviation: [Ir(ppy)₂(mdppy)]); and a rare earth metal complex such as tris(acetylacetonato)(monophenanthroline)terbium(III) (abbreviation: [Tb(acac)₃(Phen)]). These compounds mainly exhibit green phosphorescent light and have an emission peak in the wavelength range of 500 nm to 600 nm. Note that organometallic iridium complexes having a pyrimidine skeleton have distinctively high reliability or emission efficiency and thus are particularly preferable.

Other examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)2(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)2(acac)]); an organometallic iridium complex having a pyridine skeleton, such as tris(1-phenylisoquinolinato-N,C²′)iridium(III) (abbreviation: [Ir(piq)₃]), bis(1-phenylisoquinolinato-N,C2′)iridium(III) acetylacetonate (abbreviation: [Ir(piq)₂(acac)]), (3,7-diethyl-4,6-nonanedionato-x04,x06)bis[2,4-dimethyl-6-[7-(1-methylethyl)-1-isoquinolinyl-xN]phenyl-xC]iridium(III), or (3,7-diethyl-4,6-nonanedionato-x04,x06)bis[2,4-dimethyl-6-[5-(1-methylethyl)-2-quinolinyl-KN]phenyl-xC]iridium(III); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These compounds exhibit red phosphorescent light and have an emission peak in the wavelength range of 600 nm to 700 nm. Organometallic iridium complexes having a pyrazine skeleton can provide red light emission with favorable chromaticity.

Besides the above-described phosphorescent compounds, known phosphorescent compounds may be selected and used.

As the TADF material, a fullerene, a derivative thereof, an acridine, a derivative thereof, an eosin derivative, or the like can be used. Furthermore, a metal-containing porphyrin, such as a porphyrin containing magnesium (Mg), zinc (Zn), cadmium (Cd), tin (Sn), platinum (Pt), indium (In), or palladium (Pd), can be given as an example. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

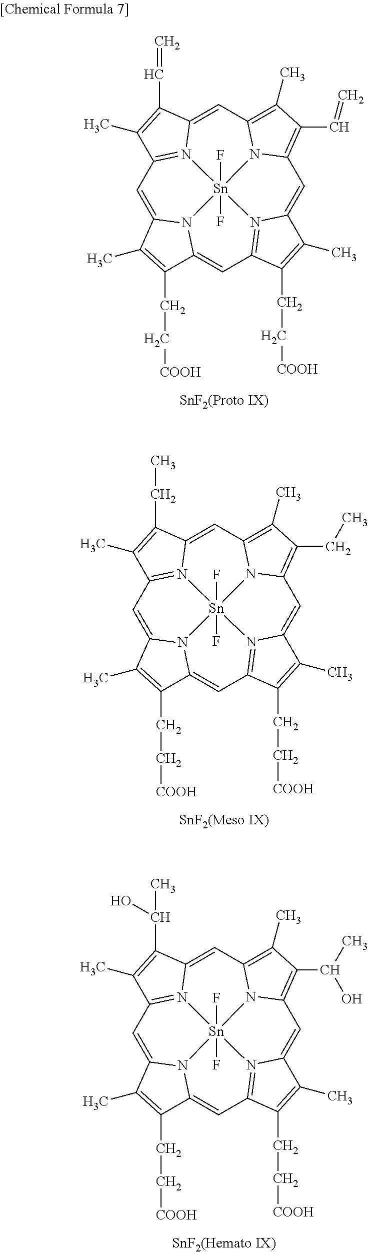

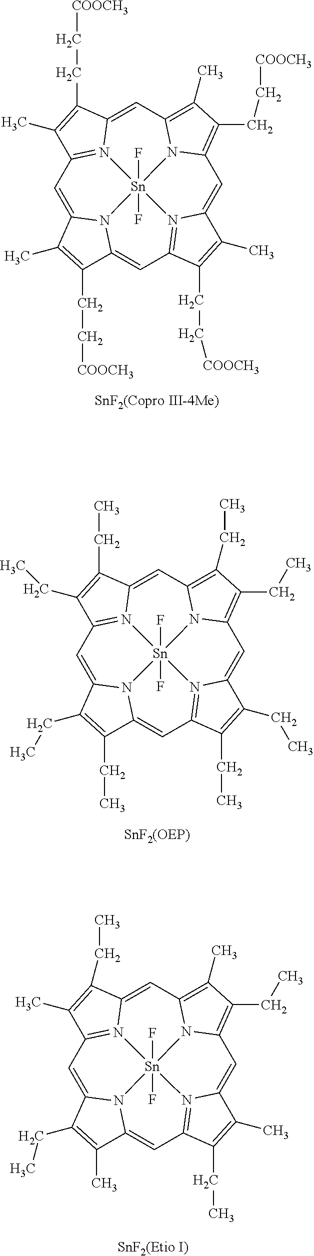

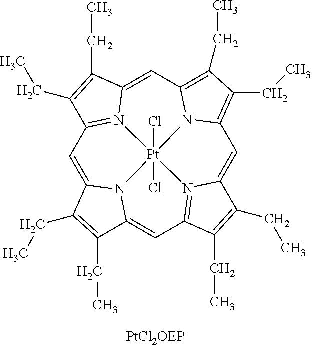

Alternatively, a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport and hole-transport properties owing to a it-electron rich heteroaromatic ring and a it-electron deficient heteroaromatic ring. Among skeletons having the it-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high electron-accepting property and high reliability. Among skeletons having the it-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. Note that a dibenzofuran skeleton and a dibenzothiophene skeleton are preferable as a furan skeleton and a thiophene skeleton, respectively. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the it-electron rich heteroaromatic ring is directly bonded to the it-electron deficient heteroaromatic ring is particularly preferable because the electron-donating property of the it-electron rich heteroaromatic ring and the electron-accepting property of the it-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the it-electron deficient heteroaromatic ring. As a π-electron rich skeleton, an aromatic amine skeleton, a phenazine skeleton, or the like can be used. As a it-electron deficient skeleton, a xanthene skeleton, athioxanthene dioxide skeleton, an oxadiazole skeleton, atriazole skeleton, an imidazole skeleton, an anthraquinone skeleton, a skeleton containing boron such as phenylborane or boranthrene, an aromatic ring having a cyano group or a nitrile group such as benzonitrile or cyanobenzene, a heteroaromatic ring, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

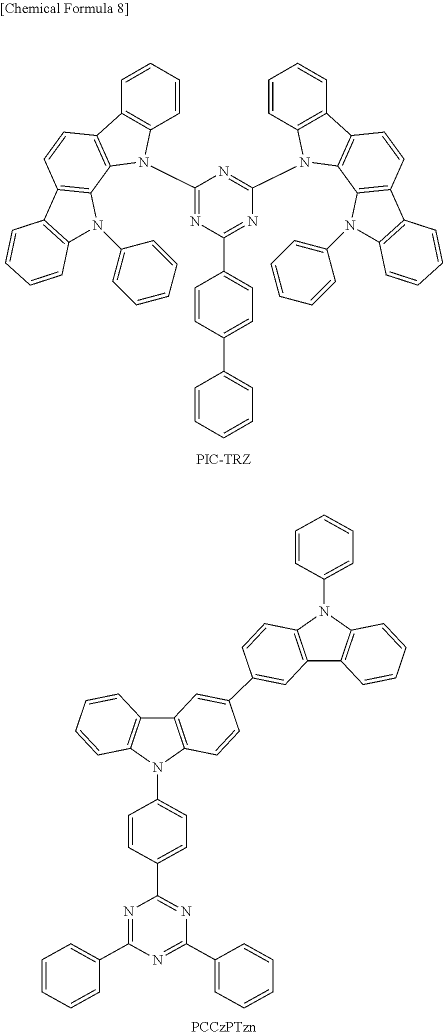 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

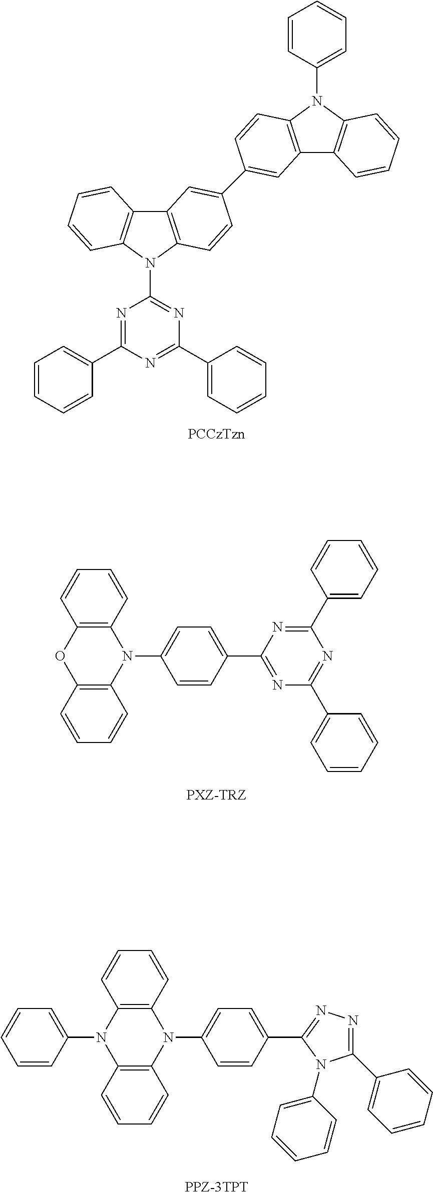 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1]

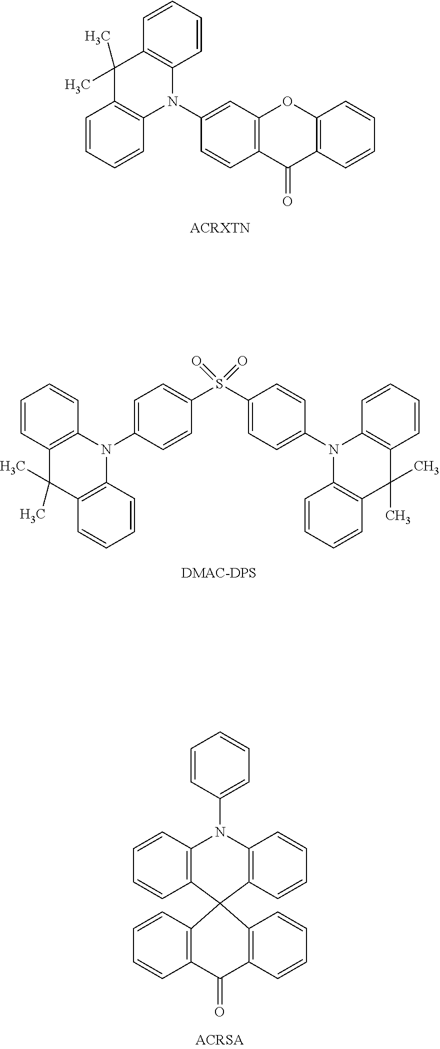 [SMILES: CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Note that the TADF material is a material having a small difference between the S₁ level and the T₁ level and having a function of converting triplet excitation energy into singlet excitation energy by reverse intersystem crossing. Thus, it is possible to upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and has a function of the TADF material capable of converting triplet excitation energy into singlet excitation energy.

Note that a phosphorescence spectrum observed at a low temperature (e.g., 77 K to 10 K) is used for an index of the T₁ level. When the level of energy with a wavelength of a line obtained by extrapolating a tangent to the fluorescence spectrum at a tail on the short wavelength side is the S₁ level and the level of energy with a wavelength of a line obtained by extrapolating a tangent to the phosphorescence spectrum at a tail on the short wavelength side is the T₁ level, the difference between the S₁ level and the T₁ level of the TADF material is preferably smaller than or equal to 0.3 eV, further preferably smaller than or equal to 0.2 eV.

When the TADF material is used as the light-emitting substance, the S₁ level of the host material is preferably higher than the S₁ level of the TADF material. In addition, the T₁ level of the host material is preferably higher than the T₁ level of the TADF material.

As the host material in the light-emitting layer, various carrier-transport materials such as materials having an electron-transport property and/or materials having a hole-transport property, and the TADF materials can be used.

The material having a hole-transport property is preferably an organic compound having an amine skeleton, a π-electron rich heteroaromatic ring skeleton, or the like. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton in the ring is preferable; specifically, a carbazole ring, a dibenzothiophene ring, or a ring in which an aromatic ring or a heteroaromatic ring is further condensed to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably a substance having an N,N-bis(4-biphenyl)amino group to enable fabricating a light-emitting device having a long lifetime.

Examples of such an organic compound include a compound having an aromatic amine skeleton, such as 4,4′-bis[N-(1-naphthyl)-N-phenylamino]biphenyl (abbreviation: NPB), N,N-diphenyl-N,N-bis(3-methylphenyl]-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 9,9′-diphenyl-9H,9′H-3,3′-bicarbazole (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above compounds, the compound having an aromatic amine skeleton and the compound having a carbazole skeleton are preferable because these compounds are highly reliable and have a high hole-transport property to contribute to a reduction in driving voltage. In addition, the organic compounds given as examples of the material having a hole-transport property that can be used for the hole-transport layer can also be used.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferable. Examples of the organic compound having a π-electron deficient heteroaromatic ring skeleton include an organic compound that has a heteroaromatic ring having a polyazole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above organic compounds, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high electron-accepting property and high reliability.

Examples of the organic compound having a it-electron deficient heteroaromatic ring skeleton include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri [3-(3-pyridyl)phenyl]benzene (abbreviation: TmPyPB), bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), or 2-[4-(2-triphenylenyl)phenyl]-1,10-phenanthroline (abbreviation: pTpPPhen); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′: 4,5]furo[2,3-b]pyrazine (abbreviation: 9mDBtBPNfpr), 9-[(3′-dibenzothiophen-4-yl)biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 2-[3′-(triphenylen-2-yl)biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn). The organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

As the TADF material that can be used as the host material, any of the materials given above as examples of the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than the S₁ level of the fluorescent substance in order that high emission efficiency be achieved. Furthermore, the T₁ level of the TADF material is preferably higher than the S₁ level of the fluorescent substance. Thus, the T₁ level of the TADF material is preferably higher than the T₁ level of the fluorescent substance.

It is also preferable to use a TADF material that emits light whose wavelength overlaps with the wavelength of the lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferable. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protecting groups. The substituents having no π bond are poor in carrier-transport performance; thus, the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably has an aromatic ring, and still further preferably has a condensed aromatic ring or a condensed heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. As the substance having an anthracene skeleton that is used as the host material, a substance having a diphenylanthracene skeleton, in particular, a substance having a 9,10-diphenylanthracene skeleton, is chemically stable and thus is preferable. The host material preferably has a carbazole skeleton, in which case the hole-injection and hole-transport properties are improved; further preferably, the host material has a benzocarbazole skeleton in which a benzene ring is further condensed to a carbazole skeleton, in which case the HOMO level thereof is shallower than that of the host material having a carbazole skeleton by approximately 0.1 eV and thus holes enter the host material easily. In particular, the host material preferably has a dibenzocarbazole skeleton, in which case the HOMO level thereof is shallower than that of the host material having a carbazole skeleton by approximately 0.1 eV, so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: aN-PNPAnth), 9-(1-naphthyl)-10-(2-naphthyl)anthracene (abbreviation: a,PADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: PN-mPNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA are preferably selected because they exhibit highly favorable characteristics.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of these mixed materials. These mixed materials are preferably selected so as to form an exciplex that exhibits light emission whose wavelength overlaps with the wavelength of the lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

A combination of a material having an electron-transport property and a material having a hole-transport property whose HOMO level is higher than or equal to the HOMO level of the material having an electron-transport property is preferable for forming an exciplex efficiently. In addition, the LUMO level of the material having a hole-transport property is preferably higher than or equal to the LUMO level of the material having an electron-transport property. Note that the LUMO levels and the HOMO levels of the materials can be derived from the electrochemical characteristics (the reduction potentials and the oxidation potentials) of the materials that are measured by cyclic voltammetry (CV).

Note that the formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side) observed by comparison of the emission spectrum of the material having a hole-transport property, the emission spectrum of the material having an electron-transport property, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed by comparison of the transient PL of the material having a hole-transport property, the transient PL of the material having an electron-transport property, and the transient PL of the mixed film of these materials. The transient PL can be rephrased as transient electroluminescence (EL). That is, the formation of an exciplex can also be confirmed by a difference in transient response observed by comparison of the transient EL of the material having a hole-transport property, the transient EL of the material having an electron-transport property, and the transient EL of the mixed film of these materials.

An electron-transport layer 114 is a layer containing a substance having an electron-transport property. The material having an electron-transport property is preferably a substance having an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. Note that an organic compound having a π-electron deficient heteroaromatic ring is preferable as the above organic compound. The organic compound having a π-electron deficient heteroaromatic ring skeleton is preferably one or more of an organic compound that has a heteroaromatic ring having a polyazole skeleton, an organic compound that has a heteroaromatic ring having a pyridine skeleton, an organic compound that has a heteroaromatic ring having a diazine skeleton, and an organic compound that has a heteroaromatic ring having a triazine skeleton, for example.

As the organic compound having an electron-transport property that can be used in the electron-transport layer 114, the organic compound that can be used as the organic compound having an electron-transport property in the light-emitting layer 113 can be similarly used. Among the above materials, the organic compound that has a heteroaromatic ring having a diazine skeleton, the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. An organic compound having a phenanthroline skeleton, such as mTpPPhen, PnNPhen, or mPPhen2P, is especially preferable, and an organic compound having a phenanthroline dimer structure, such as mPPhen2P, is further preferable because of its excellent stability.

The electron-transport layer 114 preferably has a bipolar property, that is, is preferably an electron-transport layer having a relatively high hole-transport property. Accordingly, the HOMO level of the organic compound contained in the electron-transport layer 114 is preferably greater than or equal to −5.90 eV and less than or equal to −5.00 eV, further preferably greater than or equal to −5.80 eV and less than or equal to −5.00 eV, still further preferably greater than or equal to −5.70 eV and less than or equal to −5.15 eV. Since the first electron-transport layer also needs to have a high electron-transport property as a matter of course, the LUMO level of the organic compound contained in the electron-transport layer is preferably greater than or equal to −3.15 eV and less than or equal to −2.50 eV, further preferably greater than or equal to −3.00 eV and less than or equal to −2.70 eV.

The electron-transport layer 114 may be a layer formed of a plurality of organic compounds. In the case where a plurality of organic compounds are contained in the first electron-transport layer, the HOMO level of the organic compound having the highest HOMO level is preferably within the above-described range. In the case where a plurality of organic compounds are contained in the first electron-transport layer, the LUMO level of the organic compound having the lowest LUMO level is preferably within the above-described range. In the case where the first electron-transport layer is formed of a plurality of organic compounds, at least one of the organic compounds is preferably an organic compound having an electron-transport property and at least one of the organic compounds is preferably an organic compound having a hole-transport property.

Note that the electron-transport organic compound and the hole-transport organic compound are preferably a single organic compound. In other words, it is preferable that the first electron-transport layer contain an organic compound having both an electron-transport property and a hole-transport property because of facilitating formation of a light-emitting device with favorable characteristics.

The organic compound having an electron-transport property or the organic compound having both an electron-transport property and a hole-transport property is preferably a substance having an electron mobility higher than or equal to 1×10⁻⁷ cm²/Vs, further preferably higher than or equal to 1×10⁻⁶ cm²/Vs in the case where the square root of the electric field strength [V/cm] is 600. The organic compound having a hole-transport property or the organic compound having both an electron-transport property and a hole-transport property is preferably a substance having a hole mobility higher than or equal to 1×10⁻⁷ cm²/Vs, further preferably higher than or equal to 1×10⁻⁶ cm²/Vs in the case where the square root of the electric field strength [V/cm] is 600.

The first electron-transport layer preferably contains an organic compound having an electron-transport property with an acid dissociation constant pKa of 4 or less.

The first electron-transport layer preferably contains an organic compound having an electron-transport skeleton and an organic compound having a hole-transport skeleton. Note that the organic compound having an electron-transport skeleton and the organic compound having a hole-transport skeleton are preferably a single organic compound. In other words, it is preferable that the first electron-transport layer contain an organic compound having both an electron-transport skeleton and a hole-transport skeleton because of facilitating formation of a light-emitting device with favorable characteristics.

Note that the electron-transport layer 114 may have a stacked-layer structure. In the case where the electron-transport layer 114 has a stacked-layer structure, all the stacked layers preferably have the structure described in Embodiment 1. In the case where the electron-transport layer 114 has a stacked-layer structure, the layer in contact with the light-emitting layer 113 may function as a hole-blocking layer. In the case where the electron-transport layer in contact with the light-emitting layer functions as a hole-blocking layer, the electron-transport layer is preferably formed using a material having a deeper HOMO level than the HOMO level of a material contained in the light-emitting layer by more than or equal to 0.5 eV.

A layer including an alkali metal, an alkaline earth metal, or a compound thereof such as lithium oxide (Li₂O), lithium fluoride (LiF), cesium fluoride (CsF), calcium fluoride (CaF₂), or (8-quinolinolato)lithium (abbreviation: Liq) may be provided as the electron-injection layer 115 between the electron-transport layer 114 and the second electrode 102. An electrode or a layer that is formed using a substance having an electron-transport property and that contains an alkali metal, an alkaline earth metal, or a compound thereof may be used as the electron-injection layer 115. Examples of the electrode include a substance in which electrons are added at high concentration to calcium oxide-aluminum oxide. The organic compounds given as examples of the strongly basic organic compound in Embodiment 1 can be used.

The electron-injection layer 115 may be formed using any of the above substances alone, or any of the above substances contained in a layer containing a substance having an electron-transport property.

Note that as the electron-injection layer 115, it is possible to use a layer that contains a substance having an electron-transport property (preferably an organic compound having a bipyridine skeleton) and including a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device having higher external quantum efficiency can be provided.

The second electrode 102 is an electrode including a cathode. The second electrode 102 may have a stacked-layer structure, in which case a layer in contact with the organic compound layer 103 functions as a cathode. As a substance for forming the cathode, a metal, an alloy, an electrically conductive compound, or a mixture thereof each having a low work function (specifically, lower than or equal to 3.8 eV) or the like can be used. Specific examples of such a cathode material include elements belonging to Group 1 or Group 2 of the periodic table, e.g., alkali metals such as lithium (Li) and cesium (Cs), magnesium (Mg), calcium (Ca), and strontium (Sr), alloys containing these elements (such as MgAg and AlLi), compounds containing these elements (such as lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film including any of the above materials with a low work function is provided between the second electrode 102 and the electron-transport layer, a variety of conductive materials such as Al, Ag, ITO, and indium oxide-tin oxide containing silicon or silicon oxide can be used for the cathode regardless of the work function.

In the case where the second electrode 102 is formed using a material having a visible light transmitting property, the light-emitting device can emit light from the second electrode 102 side. In the case where the first electrode 101 is formed using a material having a visible light transmitting property, the light-emitting device can emit light from the first electrode 101 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed for the formation.

Any of a variety of methods can be used for forming the organic compound layer 103, regardless of whether it is a dry process or a wet process. For example, a vacuum evaporation method, a gravure printing method, an offset printing method, a screen printing method, an ink-jet method, a spin coating method, or the like may be used.

Different film formation methods may be used to form the electrodes or the layers described above.

The structure of the layers provided between the anode and the cathode is not limited to the above-described structure. However, a light-emitting region where holes and electrons recombine is preferably positioned away from the anode and the cathode so as to inhibit quenching due to the proximity of the light-emitting region and a metal used for electrodes or carrier-injection layers.

Furthermore, in order to inhibit energy transfer from an exciton generated in the light-emitting layer, it is preferable to form the hole-transport layer or the electron-transport layer that is in contact with the light-emitting layer 113, particularly a carrier-transport layer closer to the recombination region in the light-emitting layer 113, using the light-emitting material of the light-emitting layer or a substance having a wider band gap than the light-emitting material contained in the light-emitting layer.

The structure of this embodiment can be used in combination with any of the structures of the other embodiments as appropriate.

### Embodiment 5

In this embodiment, a display apparatus of one embodiment of the present invention will be described.

The display apparatus in this embodiment can be a high-resolution display apparatus. Thus, the display apparatus in this embodiment can be used for display portions of information terminal devices (wearable devices) such as watch-type and bracelet-type information terminal devices and display portions of wearable devices that can be worn on the head, such as a VR device like a head mounted display (HMD) and a glasses-type AR device.

The display apparatus in this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

### [Display Module]

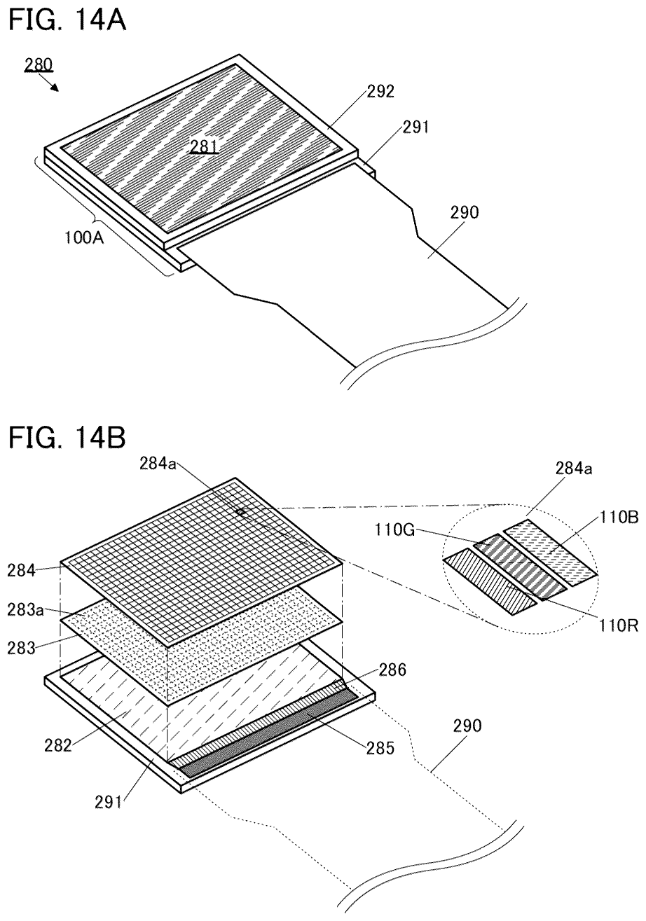

FIG. 14A is a perspective view of a display module 280. The display module 280 includes a display apparatus 100A and an FPC 290. Note that the display apparatus included in the display module 280 is not limited to the display apparatus 100A and may be any of a display apparatus 100B and a display apparatus 100E described later.

The display module 280 includes a substrate 291 and a substrate 292. The display module 280 includes a display portion 281. The display portion 281 is a region of the display module 280 where an image is displayed, and is a region where light from pixels provided in a pixel portion 284 described later can be seen.

FIG. 14B illustrates a schematic perspective view of the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 14B. The pixels 284a can employ any of the structures described in the above embodiments. FIG. 14B illustrates an example where the pixel 284a has a structure similar to that of the pixel 178 illustrated in FIG. 7.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of agate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has an extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Apparatus 100A]

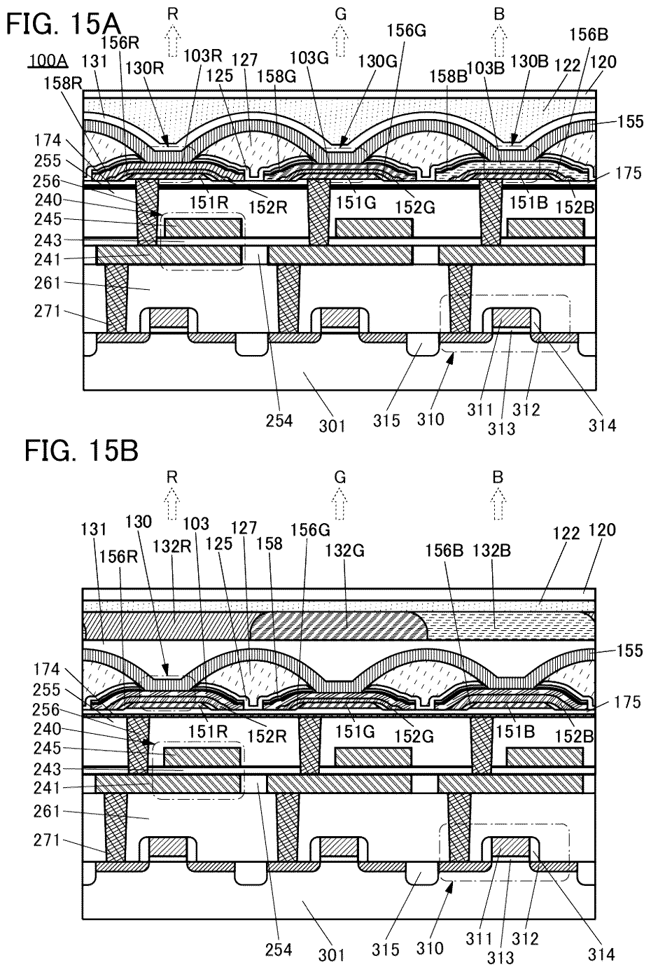

The display apparatus 100A illustrated in FIG. 15A includes a substrate 301, the light-emitting device 130R, the light-emitting device 130G, the light-emitting device 130B, a capacitor 240, and a transistor 310.

The substrate 301 corresponds to the substrate 291 in FIG. 14A and FIG. 14B. The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting device 130R, the light-emitting device 130G, and the light-emitting device 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The protective layer 158R is positioned over the organic compound layer 103R. The protective layer 158G is positioned over the organic compound layer 103G. The protective layer 158B is positioned over the organic compound layer 103B.

Each of the conductive layer 151R, the conductive layer 151G, and the conductive layer 151B is electrically connected to one of the source and the drain of the transistor 310 through a plug 256 embedded in the insulating layer 243, the insulating layer 255, the insulating layer 174, and the insulating layer 175, the conductive layer 241 embedded in the insulating layer 254, and the plug 271 embedded in the insulating layer 261. Any of a variety of conductive materials can be used for the plugs.

The protective layer 131 is provided over the light-emitting device 130R, the light-emitting device 130G, and the light-emitting device 130B. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 14A.

FIG. 15B is a variation example of the display apparatus 100A illustrated in FIG. 15A. The display apparatus illustrated in FIG. 15B includes a coloring layer 132R, a coloring layer 132G, and a coloring layer 132B, and each of the light-emitting devices 130 includes a region overlapping with one of the coloring layer 132R, the coloring layer 132G, and the coloring layer 132B. In the display apparatus illustrated in FIG. 15B, the light-emitting device 130 can emit white light, for example. The coloring layer 132R, the coloring layer 132G, and the coloring layer 132B can transmit red light, green light, and blue light, respectively, for example.

### [Display Apparatus 100B]

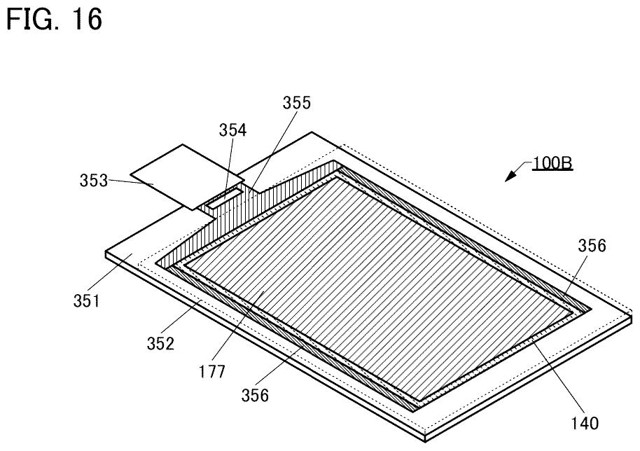

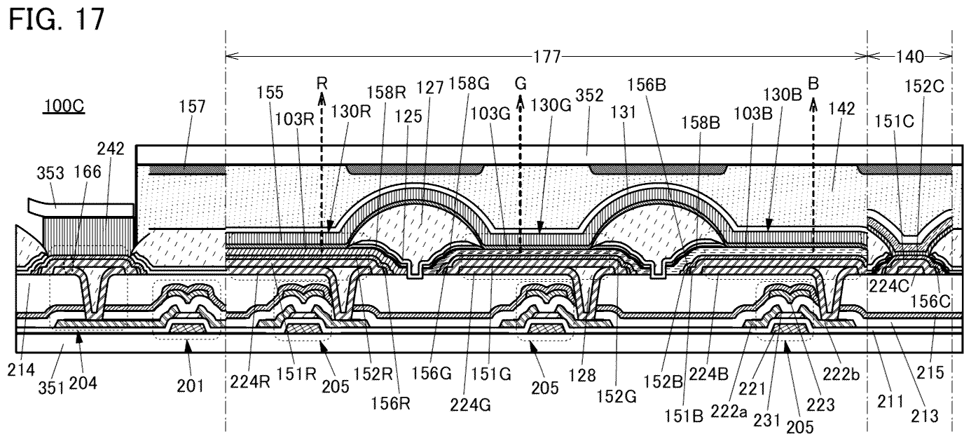

FIG. 16 illustrates a perspective view of the display apparatus 100B, and FIG. 17 illustrates a cross-sectional view of the display apparatus 100B.

In the display apparatus 100B, a substrate 352 and a substrate 351 are bonded to each other. In FIG. 16, the substrate 352 is denoted by a dashed line.

The display apparatus 100B includes the pixel portion 177, the connection portion 140, a circuit 356, a wiring 355, and the like. FIG. 16 illustrates an example in which an IC 354 and an FPC 353 are mounted on the display apparatus 100B. Thus, the structure illustrated in FIG. 16 can be regarded as a display module including the display apparatus 100B, the IC (integrated circuit), and the FPC. Here, a display apparatus in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 16 illustrates an example in which the IC 354 is provided over the substrate 351 by a COG (Chip On Glass) method, a COF (Chip on Film) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 17 illustrates an example of cross sections of part of a region including the FPC 353, part of the circuit 356, part of the pixel portion 177, part of the connection portion 140, and part of a region including an end portion of the display apparatus 100B.

### [Display Apparatus 100C]

A display apparatus 100C illustrated in FIG. 17 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 1 to Embodiment 3 can be referred to for the details of the light-emitting device 130R, the light-emitting device 130G, and the light-emitting device 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layer 224G, the conductive layer 151G, the conductive layer 152G, and the insulating layer 156G in the light-emitting device 130G and the conductive layer 224B, the conductive layer 151B, the conductive layer 152B, and the insulating layer 156B in the light-emitting device 130B are not described in detail because they are respectively similar to the conductive layer 224R, the conductive layer 151R, the conductive layer 152R, and the insulating layer 156R in the light-emitting device 130R.

In each of the conductive layer 224R, the conductive layer 224G, and the conductive layer 224B, a depression portion is formed to cover the opening provided in the insulating layer 214. A layer 128 is embedded in the depression portion.

The layer 128 has a function of filling the depression portions of the conductive layer 224R, the conductive layer 224G, and the conductive layer 224B to obtain planarity. Over the conductive layer 224R, the conductive layer 224G, the conductive layer 224B, and the layer 128, the conductive layer 151R, the conductive layer 151G, and the conductive layer 151B that are respectively electrically connected to the conductive layer 224R, the conductive layer 224G, and the conductive layer 224B are provided. Thus, the regions overlapping with the depression portions of the conductive layer 224R, the conductive layer 224G, and the conductive layer 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material that can be used for the above-described insulating layer 127, for example.

The protective layer 131 is provided over the light-emitting device 130R, the light-emitting device 130G, and the light-emitting device 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 17, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Furthermore, the space may be filled with a resin other than the frame-like adhesive layer 142.

FIG. 17 illustrates an example in which the connection portion 140 includes a conductive layer 224C obtained by processing the same conductive film as the conductive layer 224R, the conductive layer 224G, and the conductive layer 224B; the conductive layer 151C obtained by processing the same conductive film as the conductive layer 151R, the conductive layer 151G, and the conductive layer 151B; and the conductive layer 152C obtained by processing the same conductive film as the conductive layer 152R, the conductive layer 152G, and the conductive layer 152B. In the example illustrated in FIG. 17, the insulating layer 156C is provided to include a region overlapping with the side surface of the conductive layer 151C.

The display apparatus 100B has atop-emission structure. Light from the light-emitting device is emitted toward the substrate 352. For the substrate 352, a material having ahigh visible-light-transmitting property is preferably used. In the case where the light-emitting device emits infrared or near-infrared light, a material having a high transmitting property with respect to infrared or near-infrared light is preferably used. The pixel electrode contains a material that reflects visible light, and the counter electrode (the common electrode 155) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

An inorganic insulating film is preferably used as each of the insulating layer 211, the insulating layer 213, and the insulating layer 215.

An organic insulating layer is suitable for the insulating layer 214 functioning as a planarization layer.

Each of the transistor 201 and the transistor 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, the source electrode or the drain electrode of the transistor 201 is electrically connected to the FPC 353 through a conductive layer 166 and a connection layer 242. As an example, the conductive layer 166 has a stacked-layer structure of a conductive film obtained by processing the same conductive film as the conductive layer 224R, the conductive layer 224G, and the conductive layer 224B; a conductive film obtained by processing the same conductive film as the conductive layer 151R, the conductive layer 151G, and the conductive layer 151B; and a conductive film obtained by processing the same conductive film as the conductive layer 152R, the conductive layer 152G, and the conductive layer 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided between adjacent light-emitting devices, in the connection portion 140, in the circuit 356, and the like. A variety of optical members can be arranged on the outer surface of the substrate 352.

A material that can be used for the substrate 120 can be used for each of the substrate 351 and the substrate 352.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100D]

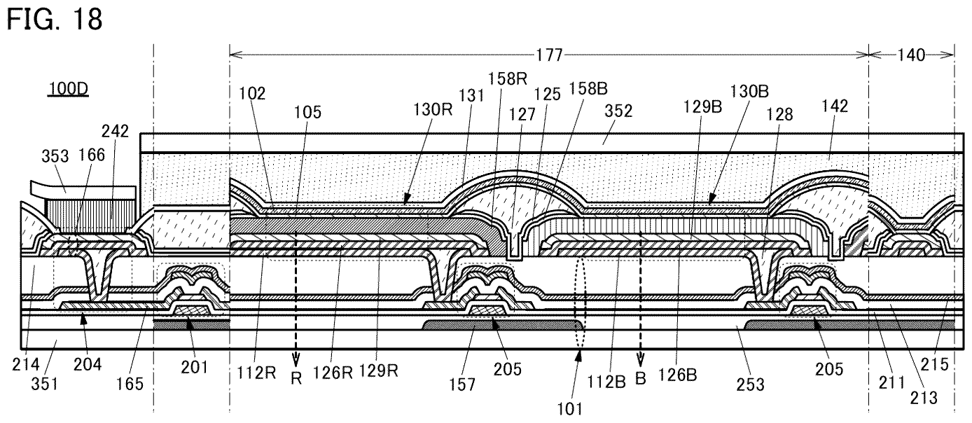

A display apparatus 100D illustrated in FIG. 18 differs from the display apparatus 100C illustrated in FIG. 17 mainly in having a bottom-emission structure.

Light from the light-emitting device is emitted toward the substrate 351. For the substrate 351, a material having a high visible-light-transmitting property is preferably used. By contrast, there is no limitation on the light-transmitting property of a material used for the substrate 352.

A light-blocking layer is preferably formed between the substrate 351 and the transistor 201 and between the substrate 351 and the transistor 205. FIG. 18 illustrates an example in which a light-blocking layer 157 is provided over the substrate 351, an insulating layer 253 is provided over the light-blocking layer, and the transistors 201 and 205 and the like are provided over the insulating layer 253.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layers 112R, 112B, 126R, 126B, 129R, and 129B. A material that reflects visible light is preferably used for the common electrode 155.

Although the light-emitting device 130G is not illustrated in FIG. 18, the light-emitting device 130G is also provided.

Although FIG. 18 and the like illustrate an example in which the top surface of the layer 128 includes a flat portion, the shape of the layer 128 is not particularly limited.

### [Display Apparatus 100E]

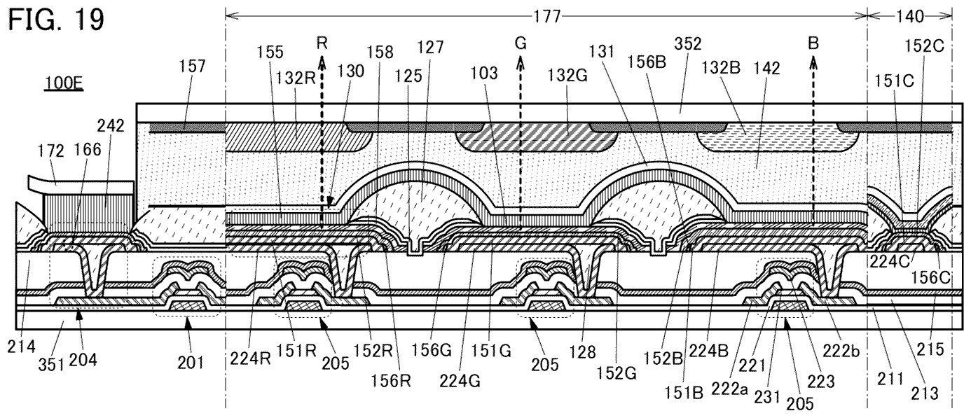

The display apparatus 100E illustrated in FIG. 19 is a variation example of the display apparatus 100C illustrated in FIG. 17 and differs from the display apparatus 100C mainly in including the coloring layer 132R, the coloring layer 132G, and the coloring layer 132B.

In the display apparatus 100E, the light-emitting device 130 includes a region overlapping with one of the coloring layer 132R, the coloring layer 132G, and the coloring layer 132B. The coloring layer 132R, the coloring layer 132G, and the coloring layer 132B can be provided on the surface of the substrate 352 on the substrate 351 side. An end portion of the coloring layer 132R, an end portion of the coloring layer 132G, and an end portion of the coloring layer 132B can overlap with the light-blocking layer 157.

In the display apparatus 100E, the light-emitting device 130 can emit white light, for example. The coloring layer 132R, the coloring layer 132G, and the coloring layer 132B can transmit red light, green light, and blue light, respectively, for example. Note that in the structure of the display apparatus 100E, the coloring layer 132R, the coloring layer 132G, and the coloring layer 132B may be provided between the protective layer 131 and the adhesive layer 142.

Although FIG. 17, FIG. 19, and the like illustrate an example in which the top surface of the layer 128 includes a flat portion, the shape of the layer 128 is not particularly limited.

This embodiment can be combined as appropriate with the other embodiments or the examples. In this specification, in the case where a plurality of structure examples are shown in one embodiment, the structure examples can be combined as appropriate.

### Embodiment 6

In this embodiment, electronic appliances of embodiments of the present invention will be described.

Electronic appliances of this embodiment include the display apparatus of one embodiment of the present invention in their display portions. The display apparatus of one embodiment of the present invention has high display performance and can be easily increased in resolution and definition. Thus, the display apparatus of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display apparatus of one embodiment of the present invention can have a high resolution, and thus can be favorably used for an electronic appliance having a relatively small display portion. Examples of such an electronic appliance include watch-type and bracelet-type information terminal devices (wearable devices) and wearable devices that can be worn on the head, such as a VR device like a head-mounted display, a glasses-type AR device, and an MR device.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

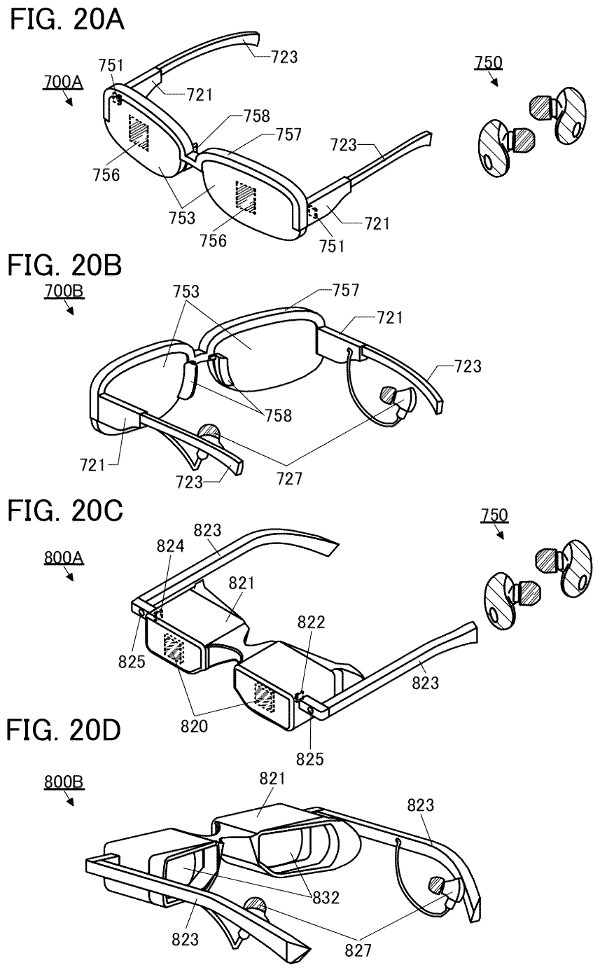

Examples of wearable devices that can be worn on the head are described with reference to FIG. 20A to FIG. 20D.

An electronic appliance 700A illustrated in FIG. 20A and an electronic appliance 700B illustrated in FIG. 20B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic appliances can be highly reliable.

The electronic appliance 700A and the electronic appliance 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliance 700A and the electronic appliance 700B, a camera capable of capturing images of the front side may be provided as the image capturing portion. Furthermore, when the electronic appliance 700A and the electronic appliance 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliance 700A and the electronic appliance 700B are provided with a battery, so that they can be charged wirelessly and/or by wire.

A touch sensor module may be provided in the housing 721.

Various touch sensors can be applied to the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

An electronic appliance 800A illustrated in FIG. 20C and an electronic appliance 800B illustrated in FIG. 20D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, the electronic appliances can be highly reliable.

The display portions 820 are positioned inside the housing 821 so as to be seen through the lenses 832. When the pair of display portions 820 display different images, three-dimensional display using parallax can be performed.

The electronic appliance 800A and the electronic appliance 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic appliance 800A may include a vibration mechanism that functions as bone-conduction earphones.

The electronic appliance 800A and the electronic appliance 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B in FIG. 20B includes earphone portions 727. Part of a wiring that connects the earphone portion 727 and the control portion may be positioned inside the housing 721 or the wearing portion 723.

Similarly, the electronic appliance 800B illustrated in FIG. 20D includes earphone portions 827. For example, a structure can be employed in which the earphone portion 827 is connected to the control portion 824 by wire.

As described above, both the glasses-type device (e.g., the electronic appliance 700A and the electronic appliance 700B) and the goggles-type device (e.g., the electronic appliance 800A and the electronic appliance 800B) are preferable as the electronic appliance of one embodiment of the present invention.

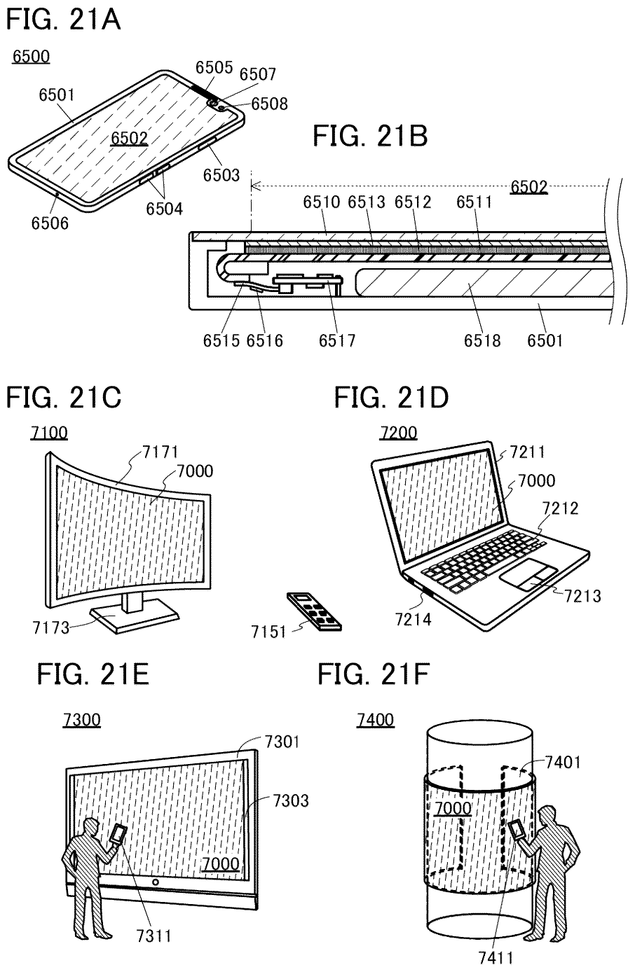

An electronic appliance 6500 illustrated in FIG. 21A is a portable information terminal device that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, the electronic appliance can be highly reliable.

FIG. 21B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used in the display panel 6511. Thus, the electronic appliance can be extremely lightweight. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby the electronic appliance can have a narrow bezel.

FIG. 21C illustrates an example of a television device. In a television device 7100, a display portion 7000 is incorporated in a housing 7171. Here, a structure in which the housing 7171 is supported by a stand 7173 is illustrated.

The display apparatus of one embodiment of the present invention can be used in the display portion 7000. Thus, the electronic appliance can be highly reliable.

Operation of the television device 7100 illustrated in FIG. 21C can be performed with an operation switch provided in the housing 7171 and a separate remote controller 7151.

FIG. 21D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, the electronic appliance can be highly reliable.

FIG. 21E and FIG. 21F illustrate examples of digital signage.

Digital signage 7300 illustrated in FIG. 21E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 21F illustrates digital signage 7400 attached to a cylindrical pillar 7401. The digital signage 7400 includes the display portion 7000 provided along a curved surface of the pillar 7401.

In FIG. 21E and FIG. 21F, the display apparatus of one embodiment of the present invention can be used in the display portions 7000. Thus, the electronic appliances can be highly reliable.

A larger area of the display portion 7000 can increase the amount of information that can be provided at a time. The display portion 7000 having a larger area attracts more attention, so that the effectiveness of the advertisement can be increased, for example.

As illustrated in FIG. 21E and FIG. 21F, it is preferable that the digital signage 7300 or the digital signage 7400 can work with an information terminal device 7311 or an information terminal device 7411, such as a smartphone that a user has, through wireless communication.

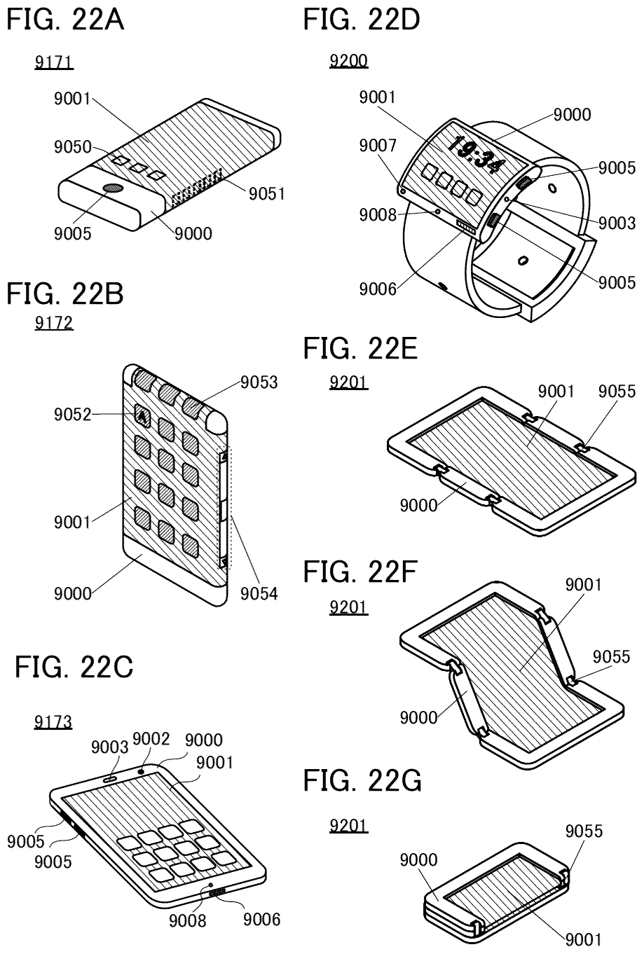

Electronic appliances illustrated in FIG. 22A to FIG. 22G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIG. 22A to FIG. 22G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic appliances in FIG. 22A to FIG. 22G are described in detail below.

FIG. 22A is a perspective view illustrating a portable information terminal 9171. The portable information terminal 9171 can be used as a smartphone, for example. Note that the portable information terminal 9171 may include the speaker 9003, the connection terminal 9006, the sensor 9007, or the like. The portable information terminal 9171 can display text and image information on its plurality of surfaces. FIG. 22A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 22B is a perspective view illustrating a portable information terminal 9172. The portable information terminal 9172 has a function of displaying information on three or more surfaces of the display portion 9001. Here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 22C is a perspective view illustrating a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface thereof.

FIG. 22D is a perspective view illustrating a watch-type portable information terminal 9200. The portable information terminal 9200 can be used as a Smartwatch (registered trademark), for example. The display surface of the display portion 9001 is curved, and display can be performed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 22E to FIG. 22G are perspective views illustrating a foldable portable information terminal 9201. FIG. 22E is a perspective view of an opened state of the portable information terminal 9201, FIG. 22G is a perspective view of a folded state thereof, and FIG. 22F is a perspective view of a state in the middle of change from one of FIG. 22E and FIG. 22G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature of greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

At least part of the structure examples, the drawings corresponding thereto, and the like described in this embodiment can be combined with the other structure examples, the other drawings, and the like as appropriate.

At least part of this embodiment can be implemented in combination with the other embodiments described in this specification as appropriate.

### Example 1

In this example, results of examining the occurrence state of peeling depending on the presence or absence and the type of a structure body layer and the shape and density of a structure body are described.

First, examination of the occurrence state of peeling depending on the presence or absence and the type of the structure body layer was performed in the following manner: samples of light-emitting apparatuses with different resolutions including five kinds of structures (Structure 1 to Structure 5) each having a different structure body layer configuration were fabricated and whether peeling occurred was observed.

(Method of fabricating sample) First, over a silicon substrate provided with a wiring, 50-nm-thick titanium (Ti), 70-nm-thick aluminum (Al), and 6-nm-thick titanium (Ti) were sequentially stacked by a sputtering method. This was heated at 300 °C in an air atmosphere for 1 hour. After the heat treatment, washing was performed and then indium tin oxide containing silicon oxide (ITSO) was deposited by a sputtering method to a thickness of 10 nm. This stacked-layer film was patterned by a photolithography method, whereby the first electrode was formed.

In addition to a 2-mm square electrode, the first electrode was patterned such that light-emitting apparatuses each having 50 ppi, 100 ppi, 200 ppi, 300 ppi, 400 ppi, and 500 ppi can be fabricated.

Next, in pretreatment for forming the light-emitting devices over the substrate, the substrate was subjected to heat treatment at 120 °C for 120 seconds, 1,1,1,3,3,3-hexamethyldisilazane (abbreviation: HMDS) was then vaporized and sprayed for 120 seconds to the substrate heated to 60 °C. This can make it difficult for the stacked-layer film formed over the first electrode to be separated from the first electrode in the fabrication process.

After that, the substrate was transferred into a vacuum evaporation apparatus in which the pressure was reduced to approximately 1×10⁻⁴ Pa, vacuum baking was performed at 170 °C for 60 minutes in a heating chamber of the vacuum evaporation apparatus, and then the substrate was cooled down for approximately 60 minutes.

Next, the substrate was fixed to a holder provided in the vacuum evaporation apparatus so that the surface on which the first electrode was formed faced downward, and an EL layer including a light-emitting layer (a hole-injection layer, a hole-transport layer, a light-emitting layer, and an electron-transport layer) was deposited by evaporation over the first electrode. After that, the structure body layer was formed by an evaporation method. Materials and deposition amounts of the structure body layer are as follows. Note that these samples were deposited by evaporation using a calibration curve of NPB.

TABLE 1

| | Structure 1 | Structure 2 | Structure 3 | Structure 4 | Structure 5 |
|---|---|---|---|---|---|
| Material | Alq₃ | PPDN:HATNA | PPDN | HATNA | None |
| | | (1:1) | | | |
| Thickness | 10 nm | 10 nm | 10 nm | 10 nm | — |

Note that Alq₃ represents tris(8-quinolinolato)aluminum(III), PPDN represents pyrazino[2,3-f][1,10]phenanthroline-1,3-dicarbonitride, and HATNA represents diquinoxalino[2,3-a:2′,3′-c]phenazine. In the structure body layer of Structure 2, PPDN and HATNA were deposited by co-evaporation such that the weight ratio of PPDN to HATNA is 1:1. Structural formulae of Alq₃, PPDN, and HATNA are shown below.

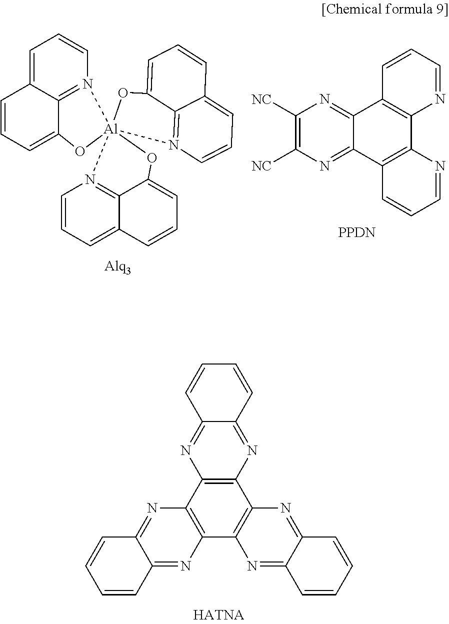

Next, the sample provided with the components up to the structure body layer was taken out from the vacuum evaporation apparatus and exposed to the atmosphere, and then aluminum oxide was deposited to a thickness of 30 nm by an ALD method, whereby a protective layer was formed. For the deposition of aluminum oxide by an ALD method, trimethylaluminum (abbreviation: TMA) and water vapor were used as a precursor and an oxidizer, respectively.

Over the protective layer, molybdenum (Mo) was deposited to a thickness of 40 nm by a sputtering method, whereby a mask layer was formed.

A photoresist was applied onto the mask layer, light exposure and development were performed, and processing was performed.

Then, the mask layer was processed using an etching gas containing CF₄, O₂, and He with use of the photoresist as a mask. The sample was immersed in a basic etchant (2.38% TMAH) for 90 seconds at room temperature using the processed mask layer as a mask, so that the photoresist was removed and part of the protective layer (corresponding to a thickness of 15 nm) was removed.

After that, optical microscopy (reflective mode, magnification of 50 times the object's size) was performed to examine whether peeling occurred, and the results are shown below. In the table below, ∘ represents a favorable result without peeling, and x represents a result with peeling.

TABLE 2

| | | Structure 1 | Structure 2 | Structure 3 | Structure 4 | Structure 5 |
|---|---|---|---|---|---|---|
| 2 | mm square | ∘ | ∘ | ∘ | ∘ | x |
| 50 | ppi | ∘ | ∘ | ∘ | ∘ | x |
| 100 | ppi | ∘ | ∘ | ∘ | ∘ | x |
| 200 | ppi | ∘ | ∘ | ∘ | ∘ | x |
| 300 | ppi | ∘ | ∘ | x | x | x |
| 400 | ppi | ∘ | ∘ | x | x | x |
| 500 | ppi | ∘ | ∘ | x | x | x |

In this manner, the presence or absence of the layer (the structure body layer) between the protective layer and the EL layer in processing by a photolithography method and the material used for the layer were found to affect whether peeling occurred.

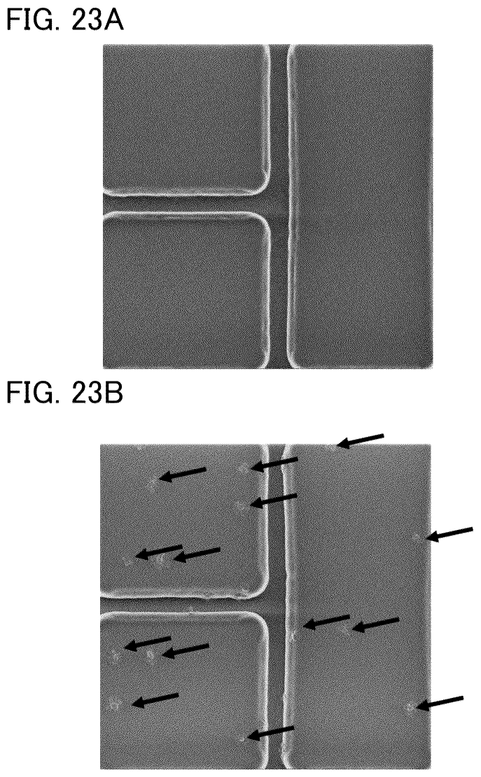

Here, FIG. 23A and FIG. 23B show scanning electron microscope (SEM) images of samples having structure body layer structures of Structure 1 and Structure 5. FIG. 23A and FIG. 23B are photographs of the samples having the configurations of the structure body layers of Structure 5 and Structure 1, respectively. Each of FIG. 23A and FIG. 23B is a photograph of a region corresponding to approximately one pixel. Note that in each of the samples in FIG. 23A and FIG. 23B, one pixel had a size of 7.92 μm×7.92 μm.

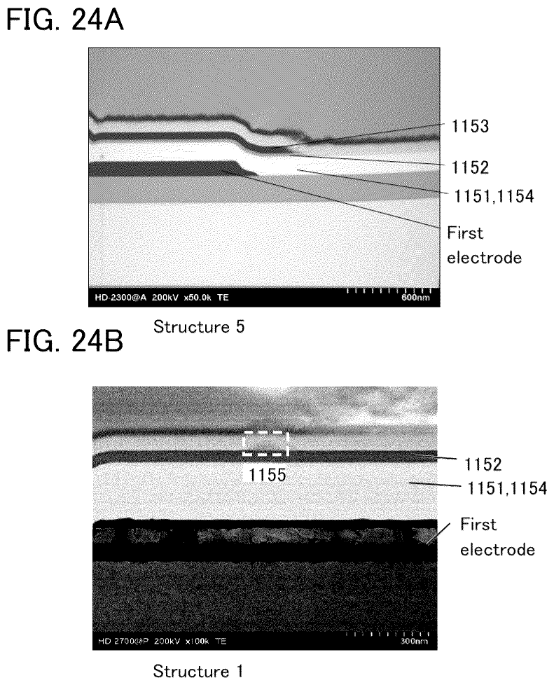

As can be seen from FIG. 23B, in the sample with the structure where peeling did not occur, such as Structure 1 or the like, a foreign matter in a clump was observed in each of the arrow portions. This is not seen in the sample with Structure 5 in which peeling occurs in FIG. 23A. FIG. 24A and FIG. 24B show cross-sectional images of samples having the structure body layer structures of Structure 5 and Structure 1, respectively, with use of a transmission electron microscope (TEM). As described above, it was found that the projecting structure was not formed in Structure 5, whereas the projecting structure body 1155 was formed in Structure 1. Note that the projecting structure body 1155 of Structure 1 is not clear because of being out of focus.

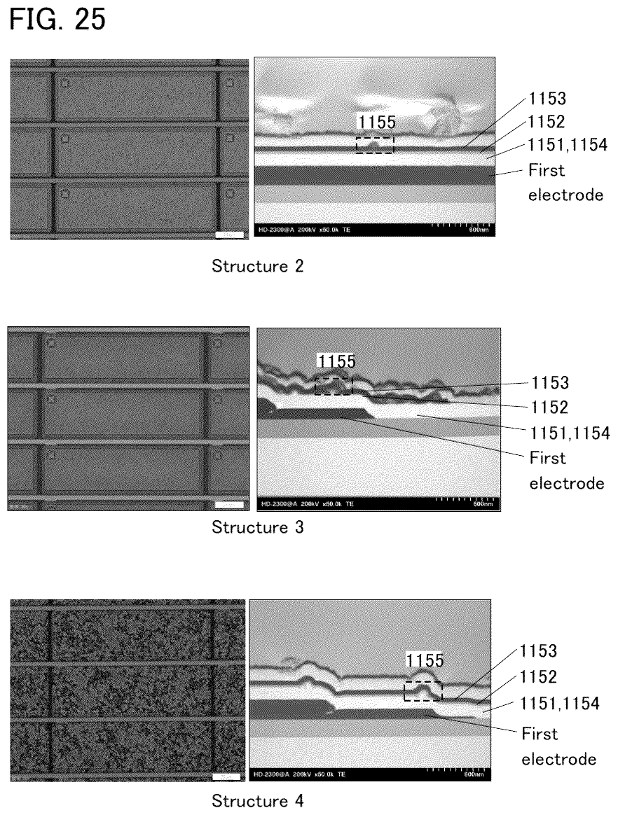

FIG. 25 shows optical micrographs (left) of the samples including the structure body layers having other structures and cross-sectional images (right) of the samples shown with the use of the TEM, and as shown in FIG. 25, the projecting structure bodies were also formed in the protective layers of Structure 2 to Structure 4.

The results of examining the sizes and densities of the projecting structure bodies included in these samples are shown below (note that Structure 5 is omitted because it includes no structure body).

TABLE 3

| | Structure 1 | Structure 2 | Structure 3 | Structure 4 |
|---|---|---|---|---|
| Width [nm] | 100 to 150 | 100 to 120 | 100 to 150 | 80 |
| Height [nm] | 20 to 50 | 60 | 60 | 60 to 80 |

In this manner, the structure body layer that forms the projecting structure body 1155 is provided below the protective layer in the organic semiconductor device employing processing by photolithography, whereby peeling of the protective layer can be inhibited as shown in Table 3. As the size of the projecting structure body, the width is preferably greater than or equal to 10 nm and less than or equal to 200 nm, further preferably greater than or equal to 80 nm and less than or equal to 150 nm, still further preferably greater than or equal to 100 nm and less than or equal to 150 nm. The height of the projecting structure body is preferably greater than or equal to 5 nm and less than or equal to 100 nm, further preferably greater than or equal to 20 nm and less than or equal to 80 nm, still further preferably greater than or equal to 20 nm and less than or equal to 60 nm.

The density of the projecting structure body is preferably greater than or equal to 0.01/μm² and less than or equal to 50/μm², further preferably greater than or equal to 0.1/μm² and less than or equal to 5/μm². Note that in the case of a high-resolution semiconductor apparatus with a resolution higher than or equal to 200 ppi, the density of the projecting structure body is preferably greater than or equal to 0.05/μm² and less than or equal to 1/μm², further preferably greater than or equal to 0.1/μm² and 0.50/μm².

As described above, when the layer that forms the projecting structure body like Structure 1 to Structure 4 is provided between the protective layer and the organic semiconductor layer, peeling in performing a photolithography method can be inhibited, so that a high-resolution organic semiconductor device can be fabricated with high yield, and an inexpensive organic semiconductor device or an organic semiconductor apparatus can be provided.

[Reference Numerals]

100: display apparatus, 100A: display apparatus, 100B: display apparatus, 100C: display apparatus,
100D: display apparatus, 100E: display apparatus, 101B: first electrode, 101G: first electrode,
101R: first electrode, 101: first electrode, 102: second electrode, 103B: organic compound layer,
103Bf: organic compound film, 103G: organic compound layer, 103Gf: organic compound film,
103R: organic compound layer, 103Rf: organic compound film, 103: organic compound layer,
104B: first EL layer, 104G: first EL layer, 104R: first EL layer, 104: first EL layer, 105: second
EL layer, 110B: subpixel, 110G: subpixel, 110R: subpixel, 110: subpixel, 111: hole-injection layer,
111C: conductive layer, 112B: conductive layer, 112R: conductive layer, 112: hole-transport layer,
113: light-emitting layer, 114: electron-transport layer, 115: electron-injection layer, 120: substrate,
122: resin layer, 125f: inorganic insulating film, 125: inorganic insulating layer, 126B: conductive
layer, 126R: conductive layer, 127a: insulating layer, 127f: insulating film, 127: insulating layer,
128: layer, 129B: conductive layer, 129R: conductive layer, 130B: light-emitting device, 130G:
light-emitting device, 130R: light-emitting device, 130: light-emitting device, 131: protective layer,
132B: coloring layer, 132G: coloring layer, 132R: coloring layer, 140: connection portion, 141:
region, 142: adhesive layer, 151B: conductive layer, 151C: conductive layer, 151f: conductive
film, 151G: conductive layer, 151R: conductive layer, 151: conductive layer, 152B: conductive
layer, 152C: conductive layer, 152f: conductive film, 152G: conductive layer, 152R: conductive
layer, 152: conductive layer, 153B: structure body layer, 153Bf: structure body layer, 153G:
structure body layer, 153Gf: structure body layer, 153R: structure body layer, 153Rf: structure
body layer, 153: structure body layer, 154: structure body layer, 155: common electrode, 156B:
insulating layer, 156C: insulating layer, 156f: insulating film, 156G: insulating layer, 156R:
insulating layer, 156: insulating layer, 157: light-blocking layer, 158B: protective layer, 158Bf:
protective film, 158G: protective layer, 158Gf: protective film, 158R: protective layer, 158Rf:
protective film, 158: protective layer, 159B: mask layer, 159Bf: mask film, 159G: mask layer,
159Gf: mask film, 159R: mask layer, 159Rf: mask film, 160: insulating layer, 161: gate insulating
layer, 162: gate electrode, 163: electrode, 164: electrode, 165: first electrode, 166: conductive layer,
167: photoelectric conversion layer, 168: light-emitting layer, 169: second electrode, 171:
insulating layer, 172: conductive layer, 173: insulating layer, 174: insulating layer, 175: insulating
layer, 176: plug, 177: pixel portion, 178: pixel, 179: conductive layer, 190B: resist mask, 190G:
resist mask, 190R: resist mask, 191: resist mask, 201: transistor, 204: connection portion, 205:
transistor, 211: insulating layer, 213: insulating layer, 214: insulating layer, 215: insulating layer,
221: conductive layer, 222a: conductive layer, 222b: conductive layer, 223: conductive layer,
224B: conductive layer, 224C: conductive layer, 224G: conductive layer, 224R: conductive layer,
231: semiconductor layer, 240: capacitor, 241: conductive layer, 242: connection layer, 243:
insulating layer, 245: conductive layer, 253: insulating layer, 254: insulating layer, 255: insulating
layer, 256: plug, 261: insulating layer, 271: plug, 280: display module, 281: display portion, 282:
circuit portion, 283a: pixel circuit, 283: pixel circuit portion, 284a: pixel, 284: pixel portion, 285:
terminal portion, 286: wiring portion, 290: FPC, 291: substrate, 292: substrate, 301: substrate, 310:
transistor, 311: conductive layer, 312: low-resistance region, 313: insulating layer, 314: insulating
layer, 315: element isolation layer, 351: substrate, 352: substrate, 353: FPC, 354: IC, 355: wiring,
356: circuit, 700A: electronic appliance, 700B: electronic appliance, 721: housing, 723: wearing
portion, 727: earphone portion, 750: earphone, 751: display panel, 753: optical member, 756:
display region, 757: frame, 758: nose pad, 800A: electronic appliance, 800B: electronic appliance,
820: display portion, 821: housing, 822: communication portion, 823: wearing portion, 824:
control portion, 825: image capturing portion, 827: earphone portion, 832: lens, 1150: base film,
1151a: organic semiconductor layer, 1151: organic semiconductor film, 1152a: protective layer,
1152: protective layer, 1153a: mask layer, 1153: mask layer, 1154a: structure body layer, 1154:
structure body layer, 1155: structure body, 1156: surface, 1175a: photomask layer, 1175: resin
film, 6500: electronic appliance, 6501: housing, 6502: display portion, 6503: power button, 6504:
button, 6505: speaker, 6506: microphone, 6507: camera, 6508: light source, 6510: protection
member, 6511: display panel, 6512: optical member, 6513: touch sensor panel, 6515: FPC, 6516:
IC, 6517: printed circuit board, 6518: battery, 7000: display portion, 7100: television device, 7151:
remote controller, 7171: housing, 7173: stand, 7200: notebook personal computer, 7211: housing,
7212: keyboard, 7213: pointing device, 7214: external connection port, 7300: digital signage, 7301:
housing, 7303: speaker, 7311: information terminal device, 7400: digital signage, 7401: pillar,
7411: information terminal device, 9000: housing, 9001: display portion, 9002: camera, 9003:
speaker, 9005: operation key, 9006: connection terminal, 9007: sensor, 9008: microphone, 9050:
icon, 9051: information, 9052: information, 9053: information, 9054: information, 9055: hinge,
9171: portable information terminal, 9172: portable information terminal, 9173: tablet terminal,
9200: portable information terminal, 9201: portable information terminal

1. A method for fabricating an organic semiconductor device, comprising:
forming a first layer over a first electrode;
forming a second layer over the first layer, the second layer comprising a structure body having a projecting shape;
forming a third layer over the first layer and the second layer; and
removing part of the first layer using the third layer as a mask,
wherein the first layer is an organic semiconductor layer, and
wherein the third layer is formed using a material different from materials for the first layer and the second layer.

2. A method for fabricating an organic semiconductor device, comprising:
forming a first layer over a first electrode;
forming a second layer over the first layer, the second layer comprising a structure body having a projecting shape;
forming a third layer over the first layer and the second layer;
forming a fourth layer over the third layer; and
removing part of the first layer using at least one of the third layer and the fourth layer as a mask,
wherein the first layer is an organic semiconductor layer,
wherein each of the third layer and the fourth layer is formed using a material different from materials for the first layer and the second layer, and
wherein the material for the third layer is different from the material for the fourth layer.

3. The method for fabricating an organic semiconductor device, according to claim 2,
wherein the fourth layer comprises an inorganic compound.

4. The method for fabricating an organic semiconductor device, according to claim 3,
wherein the fourth layer is one or more selected from aluminum, indium, tungsten, molybdenum, gallium, zinc, silicon, and an oxide or a nitride thereof.

5. The method for fabricating an organic semiconductor device, according to claim 1,
wherein the material for the second layer has a glass transition temperature lower than or equal to 120 °C.

6. The method for fabricating an organic semiconductor device, according to claim 1,
wherein a width of the structure body is greater than or equal to 10 nm and less than or equal to 200 nm, and a height of the structure body is greater than or equal to 5 nm and less than or equal to 100 nm.

7. The method for fabricating an organic semiconductor device, according to claim 1,
wherein a width of the structure body is greater than or equal to 100 nm and less than or equal to 150 nm, and a height of the structure body is greater than or equal to 20 nm and less than or equal to 60 nm.

8. The method for fabricating an organic semiconductor device, according to claim 1,
wherein a density of the structure body is greater than or equal to 0.1/μm² and less than or equal to 0.5/μm².

9. The method for fabricating an organic semiconductor device, according to claim 1,
wherein the material for the second layer comprises an organometallic complex.

10. The method for fabricating an organic semiconductor device, according to claim 1,
wherein the third layer comprises an inorganic compound.

11. The method for fabricating an organic semiconductor device, according to claim 10,
wherein the third layer is one or more selected from aluminum, indium, tungsten, molybdenum, gallium, zinc, silicon, and an oxide or a nitride thereof.

12. The method for fabricating an organic semiconductor device, according to claim 11,
wherein the third layer comprises aluminum oxide.

13. A method for fabricating an organic semiconductor device, according to claim 1,
wherein the first layer comprises a light-emitting layer.

14. A method for fabricating an organic semiconductor device, according to claim 1,
wherein the first layer comprises a photoelectric conversion layer.
